(19) United States
(12) Patent Application Publication
(10) Pub. No.: US 2024/0215405 A1
(43) Pub. Date: Jun. 27, 2024

(54) DISPLAY APPARATUS

(71) Applicant: LG Display Co., Ltd., Seoul (KR)

(72) Inventors: Sejong Seong, Paju-si (KR); KyungMin Kim, Paju-si (KR); Hyemin Park, Paju-si (KR); SeHong Park, Paju-si (KR); Wonrae Kim, Paju-si (KR); Inae Choi, Paju-si (KR); SeoHyun Nam, Paju-si (KR)

(73) Assignee: LG Display Co., Ltd., Seoul (KR)

(21) Appl. No.: 18/397,456

(22) Filed: Dec. 27, 2023

(30) Foreign Application Priority Data
Dec. 27, 2022 (KR) 10-2022-0185346
Dec. 19, 2023 (KR) 10-2023-0186100

(51) Int. Cl. H10K 59/80; H10K 59/131

(52) U.S. Cl. CPC H10K 59/878; H10K 59/131; H10K 59/351

(57) ABSTRACT

A display apparatus is discussed, which can improve light extraction efficiency of light emitted from a light emitting element layer. In one example, the display apparatus includes a substrate having a plurality of pixels with a plurality of subpixels, a pattern portion disposed on the substrate and formed to be concave between the plurality of subpixels, a reflective portion on the pattern portion, and a plurality of lines for driving the plurality of subpixels. The plurality of subpixels include a light emission area and a non-light emission area adjacent to the light emission area, and the plurality of lines are disposed in the non-light emission area. Further, the pattern portion is provided to surround the light emission area, and at least one of the plurality of lines partially overlaps the pattern portion.

### CROSS-REFERENCE TO RELATED APPLICATIONS

This application claims priority to Korean Patent Application No. 10-2022-0185346 filed in the Republic of Korea on Dec. 27, 2022 and Korean Patent Application No. 10-2023-0186100 filed in the Republic of Korea on Dec. 19, 2023, the entire contents of all these applications being hereby expressly incorporated by reference into the present application.

### BACKGROUND

### Field

The present disclosure relates to a display apparatus for displaying an image.

### Discussion of the Related Art

An organic light emitting display apparatus has a high response speed and a low power consumption and also self-emits light without requiring a separate light source unlike a liquid crystal display apparatus. As a result, it provides a good viewing angle and can be manufactured to be thin. Thus the organic light emitting display apparatus has received attention as a next-generation flat panel display apparatus.

Such a display apparatus displays an image through the light emission of a light emitting element layer that includes a light emitting layer interposed between two electrodes.

However, the light extraction efficiency of the display apparatus can be reduced as some of the light emitted from the light emitting element layer may not be emitted to the outside due to the total reflection on the interface between the light emitting element layer and an electrode and/or between a substrate and an air layer.

### SUMMARY OF THE DISCLOSURE

The present disclosure has been made in view of the above limitations and other issues associated with the related art.

It is an object of the present disclosure to provide a display apparatus that can improve light extraction efficiency of light emitted from a light emitting element layer.

It is another object of the present disclosure to provide a display apparatus in which a luminance retention rate and light extraction efficiency can be further improved through light extraction from a non-light emission area.

It is still another object of the present disclosure to provide a display apparatus in which light can be extracted from a non-light emission area adjacent to a corner portion of a light emission area.

It is further still another object of the present disclosure to provide a display apparatus in which light extraction efficiency can be maximized through reflective lines disposed in a non-light emission area.

It is further still another object of the present disclosure to provide a display apparatus in which color mixture between subpixels can be prevented from occurring.

It is further still another object of the present disclosure to provide a display apparatus in which colors and color viewing angles of subpixels can be maintained.

It is further still another object of the present disclosure to provide a display apparatus in which a color temperature of a white subpixel may be improved.

It is further still another object of the present disclosure to provide a display apparatus in which usage lifespan may be improved.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a display apparatus comprising a substrate having a plurality of pixels having a plurality of subpixels, a pattern portion disposed on the substrate and formed to be concave between the plurality of subpixels, a reflective portion on the pattern portion, and a plurality of lines for driving the plurality of subpixels, wherein the plurality of subpixels include a light emission area and a non-light emission area adjacent to the light emission area, the plurality of lines are disposed in the non-light emission area, the pattern portion is provided to surround the light emission area, and at least one of the plurality of lines partially overlaps the pattern portion.

In accordance with another aspect of the present disclosure, the above and other objects can be accomplished by the provision of a display apparatus comprising a substrate including a plurality of subpixels having a light emission area and a non-light emission area adjacent to the light emission area, a pattern portion formed to be concave on the substrate, surrounding the light emission area of the plurality of subpixels, a reflective portion on the pattern portion, and a plurality of lines for driving the plurality of subpixels, wherein the non-light emission area includes a first area adjacent to the light emission area and a second area adjacent to the first area and spaced apart from the light emission area, and the line, which is disposed in the first area, among the plurality of lines is a reflective line.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic plan view illustrating a display apparatus according to one embodiment of the present disclosure;

FIG. 2 is a schematic plan view illustrating an example of one pixel shown in FIG. 1;

FIG. 3 is a schematic cross-sectional view taken along line I-I′ shown in FIG. 2;

FIG. 4 is an enlarged view illustrating a portion A shown in FIG. 3;

FIG. 5 is an image illustrating an example of light extraction characteristics of a non-light emission area of a display apparatus according to one embodiment of the present disclosure;

FIG. 6 is an enlarged view illustrating a portion A shown in FIG. 3, illustrating a color filter disposed in a non-light emission area;

FIG. 7 is a schematic cross-sectional view taken along line II-II′ shown in FIG. 2;

FIG. 8 is a schematic cross-sectional view taken along line III-III′ shown in FIG. 2;

FIG. 9 is a schematic cross-sectional view taken along line IV-IV′ shown in FIG. 2;

FIG. 10 is a schematic cross-sectional view taken along line V-V′ shown in FIG. 2;

FIG. 11 is a schematic plan view illustrating a plurality of pixels of a display apparatus according to one embodiment of the present disclosure;

FIG. 12 is a schematic cross-sectional view taken along line VI-VI′ shown in FIG. 11;

FIG. 13 is a schematic plan view illustrating a display apparatus according to another embodiment of the present disclosure;

FIG. 14 is a schematic cross-sectional view taken along line VII-VII′ shown in FIG. 13;

FIG. 15A is an image illustrating light extraction characteristics of a red subpixel of a display apparatus according to a comparative example;

FIG. 15B is an image illustrating light extraction characteristics of a red subpixel of a display apparatus according to another embodiment of the present disclosure;

FIG. 16 is schematic cross-sectional view taken along line VIII-VIII′ shown in FIG. 13;

FIG. 17A is an image illustrating light extraction characteristics of a white subpixel of a display apparatus according to a comparative example;

FIG. 17B is an image illustrating light extraction characteristics of a white subpixel of a display apparatus according to another embodiment of the present disclosure;

FIG. 18 is schematic cross-sectional view illustrating another example of FIG. 14;

FIG. 19A is an image illustrating light extraction characteristics of another white subpixel of a display apparatus according to a comparative example; and

FIG. 19B is an image illustrating light extraction characteristics of another white subpixel of a display apparatus according to another embodiment of the present disclosure.

### DETAILED DESCRIPTION OF THE EMBODIMENTS

Reference will now be made in detail to the embodiments of the present disclosure, examples of which are illustrated in the accompanying drawings.

Wherever possible, the same reference numbers will be used throughout the drawings to refer to the same or like parts.

Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part can be added unless ‘only’ is used. The terms of a singular form can include plural forms unless referred to the contrary.

In construing an element, the element is construed as including an error range although there is no explicit description.

In describing a position relationship, for example, when a position relation between two parts is described as ‘on’, ‘over’, ‘under’, and ‘next’, etc., one or more other parts can be disposed between the two parts unless ‘just’ or ‘direct’ is used.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms, and may not define order or sequence.

These terms are only used to distinguish one element from another. For example, a first element could be termed a second element, and, similarly, a second element could be termed a first element, without departing from the scope of the present disclosure.

Further, “X-axis direction”, “Y-axis direction” and “Z-axis direction” should not be construed by a geometric relation only of a mutual vertical relation and can have broader directionality within the range that elements of the present disclosure can act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure can be partially or overall coupled to or combined with each other and can be variously inter-operated with each other and driven technically as those skilled in the art can sufficiently understand.

The embodiments of the present disclosure can be carried out independently from each other or can be carried out together in co-dependent relationship.

Hereinafter, the preferred embodiments of the present disclosure will be described in detail with reference to the accompanying drawings. All the components of each display apparatus according to all embodiments of the present disclosure are operatively coupled and configured.

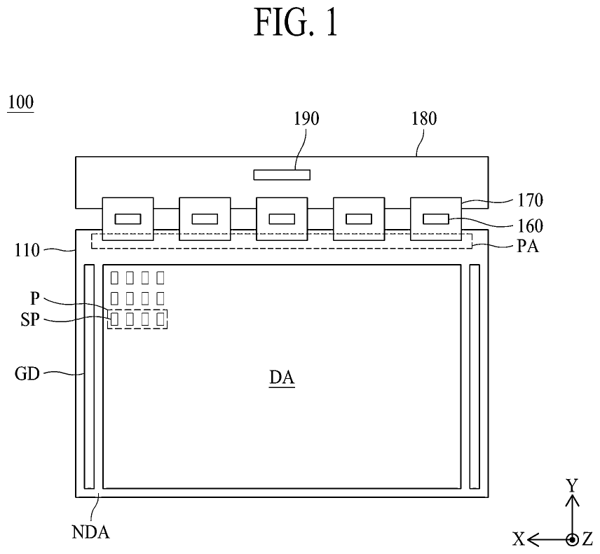

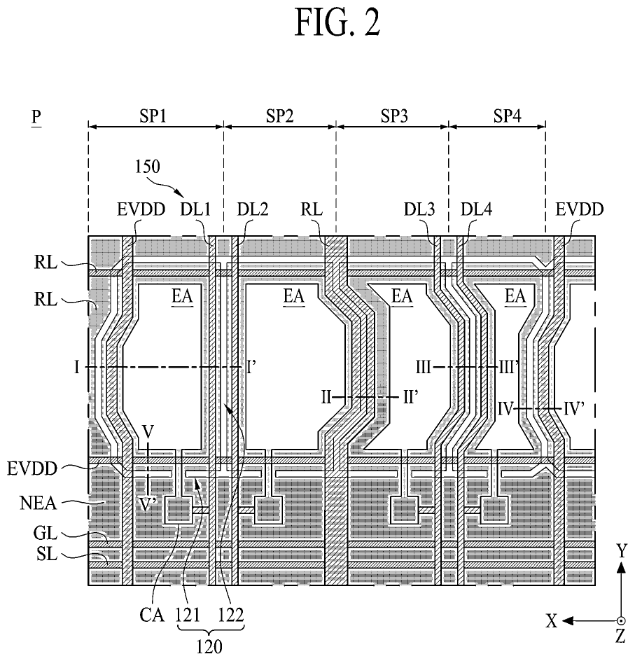

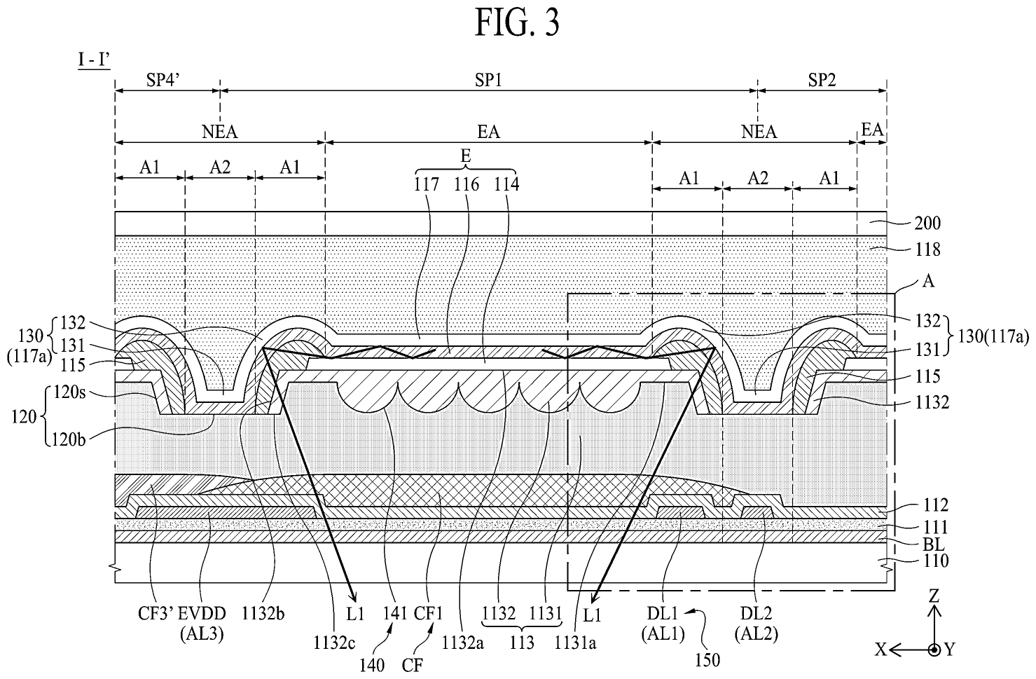

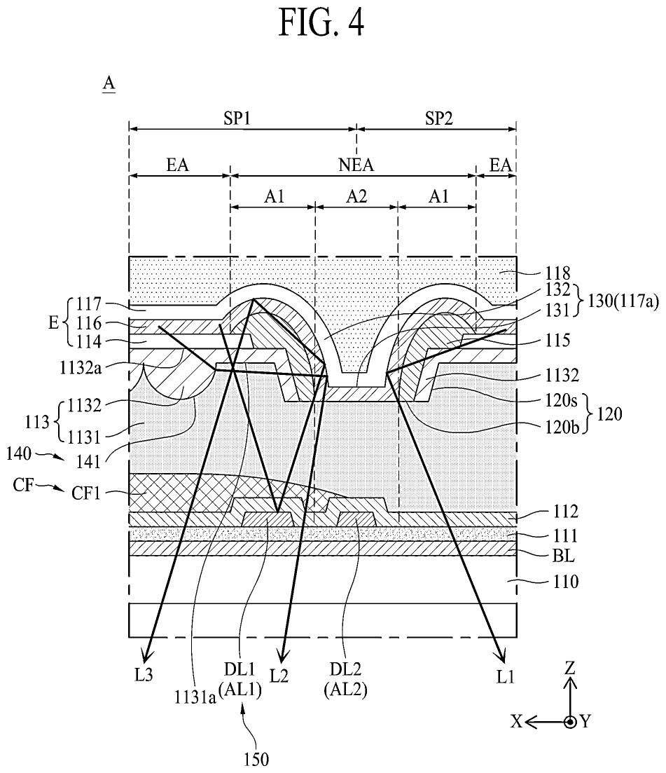

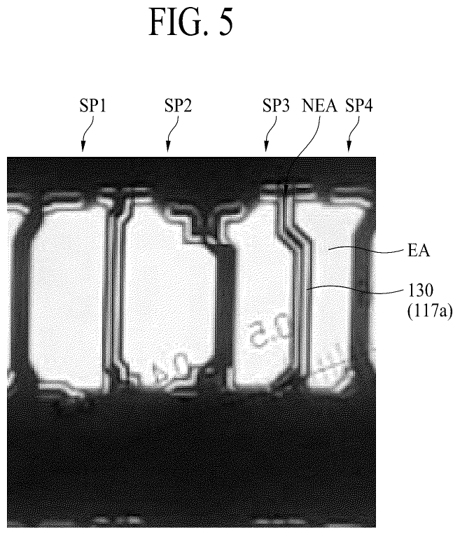

FIG. 1 is a schematic plan view illustrating a display apparatus according to one embodiment of the present disclosure, FIG. 2 is a schematic plan view illustrating one pixel shown in FIG. 1, FIG. 3 is a schematic cross-sectional view taken along line I-I′ shown in FIG. 2, FIG. 4 is an enlarged view illustrating a portion A shown in FIG. 3, and FIG. 5 is an image illustrating light extraction characteristics of a non-light emission area of a display apparatus according to one embodiment of the present disclosure.

Referring to FIGS. 1 to 5, a display apparatus 100 according to one embodiment of the present disclosure includes a substrate 110 having a plurality of pixels P having a plurality of subpixels SP, a pattern portion 120 disposed on the substrate 110 and formed to be concave between the plurality of subpixels SP, a reflective portion 130 on the pattern portion 120, and a plurality of lines 150 for driving the plurality of subpixels SP. The plurality of subpixels SP can include a light emission area EA and a non-light emission area NEA adjacent to the light emission area EA. The pattern portion 120 can be provided to surround the light emission area EA. The plurality of lines 150 can be disposed in the non-light emission area NEA. In this case, at least one of the plurality of lines 150 can partially overlap the pattern portion 120. For example, as shown in FIG. 3, the first data line DL1 can partially overlap an inclined surface 120s and a bottom surface 120b of the pattern portion 120.

The line 150 overlapped with the pattern portion 120 can be a reflective line. The reflective line according to one example can mean a line made of a material capable of reflecting light emitted from the light emission area EA, but the present disclosure is not limited thereto. The reflective line can mean a line made of a material capable of reflecting light emitted from the light emission area EA and reflected by the reflective portion 130. The reflective line according to another example can include an upper surface in a direction facing the reflective portion 130, and can mean a line in which the upper surface of the reflective line is made of a reflective material. Meanwhile, the reflective line can mean a line capable of reflecting 90% or more of reflectance in a visible ray area. For example, the reflective line can be a line including silver (Ag) and/or aluminum (Al). The visible ray area can mean an area having a wavelength of 380 nm to 780 nm.

Therefore, in the display apparatus 100 according to one embodiment of the present disclosure, as shown in FIG. 4, light emitted from the light emission area EA and directed toward the line 150 can be primarily reflected by the line 150 and can be secondarily reflected by the reflective portion 130. The light secondarily reflected by the reflective portion 130 can be emitted to the light emission area EA or the non-light emission area NEA of the subpixel SP, which is emitted by being thirdly reflected by a reflective electrode 117 of a light emitting element layer E included in the plurality of subpixels SP.

Therefore, the display apparatus 100 according to one embodiment of the present disclosure can extract light even through the line disposed in the non-light emission area NEA, and thus overall light extraction efficiency can be improved.

The light emission area EA is an area from which light is emitted, and can be included in a display area DA. A non-display area NDA can be disposed in the periphery of the display area DA. The non-light emission area NEA is an area from which light is not emitted, and can be included in the display area DA. The non-light emission area NEA can be expressed as a term of a peripheral area. The non-light emission area NEA can include a first area A1 adjacent to the light emission area EA and a second area A2 adjacent to the first area A1 and spaced apart from the light emission area EA. As shown in FIG. 3, the plurality of lines 150 can be disposed in the non-light emission area NEA, for example, the first area A1 and/or the second area A2 (i.e., at least one of the first area A1 and the second area A2). The second area A2 according to one example can mean a predetermined area that overlaps a boundary portion (or the boundary line) between the plurality of subpixels SP. For example, as shown in FIG. 3, the second area A2 can mean an area having a width wider than the boundary portion (or the boundary line) while overlapping the boundary portion (or the boundary line) of the plurality of subpixels SP. In the display apparatus 100 according to one embodiment of the present disclosure, the line disposed in the first area A1 is provided as a reflective line, whereby light extraction efficiency can be improved.

As shown in FIG. 4, the first area A1 can be an area in which a bank 115 of each of the plurality of subpixels SP is disposed. The second area A2 can be an area between the banks 115 included in each of the plurality of subpixels SP. For example, the first area A1 of the second subpixel SP2 can be an area between the light emission area EA of the second subpixel SP2 and the second area A2 between the first subpixel SP1 and the second subpixel SP2. The second area A2 can be a bankless area (e.g., without banks) between the first subpixel SP1 and the second subpixel SP2.

The display apparatus 100 according to one embodiment of the present disclosure is provided with the reflective portion 130 on the pattern portion 120 between the plurality of subpixels SP, so that light, which is directed toward an adjacent subpixel SP, among light emitted from the light emission area EA, can be reflected toward the light emission area EA of the subpixel SP for emitting light and/or the non-light emission area NEA of the subpixel SP for emitting light. Therefore, the display apparatus 100 according to one embodiment of the present disclosure can improve light extraction efficiency of the subpixel SP for emitting light.

Since the pattern portion 120 according to one example is provided to surround the light emission area EA of each of the plurality of subpixels SP, the reflective portion 130 can be also provided to surround the light emission area EA of each of the plurality of subpixels SP. The light reflected by the reflective portion 130 can be emitted to the outside through a lower surface of the substrate 110 in the non-light emission area NEA spaced apart from the light emission area EA of the subpixel SP for emitting light and/or the light emission area EA of the subpixel SP for emitting light.

The pattern portion 120 according to one example can be formed to be concave near the non-light emission area NEA. For example, the pattern portion 120 can be formed to be concave in an overcoat layer 113 (shown in FIG. 3) on the substrate 110. As shown in FIG. 2, the pattern portion 120 can be provided to surround the light emission area EA. The pattern portion 120 can be disposed to be spaced apart from the light emission area EA. In FIG. 2, point hatching (or shading) is to indicate the bank (115 shown in FIG. 3). The pattern portion 120 according to one example can be provided to surround the light emission area EA in the form of a slit or a trench. For example, a width of the pattern portion 120 can be formed to be reduced from the reflective portion 130 toward the substrate 110. Further, as shown in FIG. 3, the pattern portion 120 can include an area exposed without being covered by the bank 115. Therefore, the pattern portion 120 can be expressed as terms such as a groove, a slit, a trench, a bank slit and a bank trench.

The reflective portion 130 according to one example can be formed to be concave along a profile of the pattern portion 120 formed to be concave near the non-light emission area NEA, thereby being formed to be concave near the non-light emission area NEA. The reflective portion 130 can be made of a material capable of reflecting light, and can reflect light, which is emitted from the light emission area EA and directed toward the adjacent subpixel SP, toward the light emission area EA of the subpixel SP for emitting light. As shown in FIG. 3, since the reflective portion 130 is disposed to be inclined while surrounding the light emission area EA, the reflective portion 130 can be expressed as terms such as a side reflective portion or an inclined reflective portion. As shown in FIGS. 3 and 4, the reflective portion 130 can include a flat surface 131 disposed in the second area A2 and a curved surface 132 connected to the flat surface 131. The flat surface 131 can be disposed in parallel with the bottom surface 120b (shown in FIG. 4) of the pattern portion 120. The curved surface 132 can be formed in a rounded shape along a profile of the inclined surface 120s of the pattern portion 120. Most of the light emitted from the subpixel SP for emitting light can be reflected by the curved surface 132 and then emitted to the light emission area EA of the subpixel SP for emitting light or the non-light emission area NEA of the subpixel SP for emitting light.

Meanwhile, the display apparatus 100 according to one embodiment of the present disclosure can be implemented in a bottom emission type in which light emitted from the light emission area EA is emitted to the lower surface of the substrate 110. Therefore, in the display apparatus 100 according to one embodiment of the present disclosure, the light emitted to the lower surface of the substrate 110 can be the light in which direct light emitted from the light emission area EA and directly emitted to the lower surface of the substrate 110 and reflective light obtained by reflecting the light, which is emitted from the light emission area EA and directed toward the adjacent subpixel SP, by the reflective portion 130 and emitting the light to the lower surface of the substrate 110 are combined with each other. The reflective light can include reflective light that is wave-guided on an interface between a light emitting layer and an electrode and reflected by the reflective portion 130 and then emitted to the substrate 110. Therefore, the display apparatus 100 according to one embodiment of the present disclosure can more improve light extraction efficiency than the display apparatus in which the reflective portion 130 formed to be concave is not provided.

Hereinafter, reference to FIGS. 1 to 5, the display apparatus 100 according to an embodiment of the present specification will be described in more detail.

Referring to FIGS. 1 and 3, the display apparatus 100 according to one embodiment of the present disclosure can include a display panel having a gate driver GD, a light extraction portion 140 overlapping a light emission area EA, a source drive integrated circuit (IC) 160, a flexible film 170, a circuit board 180, and a timing controller 190.

The display panel can include a substrate 110 and an opposite substrate 200 (shown in FIG. 3).

The substrate 110 can include a thin film transistor, and can be a transistor array substrate, a lower substrate, a base substrate, or a first substrate. The substrate 110 can be a transparent glass substrate or a transparent plastic substrate. The substrate 110 can include a display area DA and a non-display area NDA. For example, the display area DA can be disposed in a central portion of the display panel. The display area DA can include a plurality of pixels P.

The opposite substrate 200 can encapsulate (or seal) the display area DA disposed on the substrate 110. For example, the opposite substrate 200 can be bonded to the substrate 110 via an adhesive member (or clear glue). The opposite substrate 200 can be an upper substrate, a second substrate, or an encapsulation substrate.

The gate driver GD supplies gate signals to the gate lines in accordance with the gate control signal input from the timing controller 190. The gate driver GD can be formed on one side of the display area DA or in the non-display area NDA outside both sides of the display area DA in a gate driver in panel (GIP) method, as shown in FIG. 1.

The non-display area NDA is an area on which an image is not displayed, and can be a peripheral area, a signal supply area, an inactive area or a bezel area. The non-display area NDA can be configured to be in the vicinity of the display area DA. For example, the non-display area NDA can be disposed to surround the display area DA.

A pad area PA can be disposed in the non-display area NDA. The pad area PA can supply a power source and/or a signal for outputting an image to the pixel P provided in the display area DA. Referring to FIG. 1, the pad area PA can be provided above the display area DA.

The source drive IC 160 receives digital video data and a source control signal from the timing controller 190. The source drive IC 160 converts the digital video data into analog data voltages in accordance with the source control signal and supplies the analog data voltages to the data lines. When the source drive IC 160 is manufactured as a driving chip, the source drive IC 160 can be packaged in the flexible film 170 in a chip on film (COF) method or a chip on plastic (COP) method.

Pads, such as data pads, can be formed in the non-display area NDA of the display panel. Lines connecting the pads with the source drive IC 160 and lines connecting the pads with lines of the circuit board 180 can be formed in the flexible film 170. The flexible film 170 can be attached onto the pads by using an anisotropic conducting film, whereby the pads can be connected with the lines of the flexible film 170.

The circuit board 180 can be attached to the flexible films 170. A plurality of circuits implemented as driving chips can be packaged in the circuit board 180. For example, the timing controller 190 can be packaged in the circuit board 180. The circuit board 180 can be a printed circuit board or a flexible printed circuit board.

The timing controller 190 receives the digital video data and a timing signal from an external system board through a cable of the circuit board 180. The timing controller 190 generates a gate control signal for controlling an operation timing of the gate driver GD and a source control signal for controlling the source drive ICs 160 based on the timing signal. The timing controller 190 supplies the gate control signal to the gate driver GD, and supplies the source control signal to the source drive ICs 160.

Referring to FIGS. 2 and 3, the substrate 110 according to an example can include the light emission area EA and the non-light emission area NEA.

The substrate 110 according to an example can include gate lines, data lines, pixel driving power lines, and a plurality of pixels P. Each of the plurality of pixels P can include a plurality of subpixels SP that can be defined by the gate lines and the data lines.

Meanwhile, at least four subpixels, which are provided to emit different colors and disposed to be adjacent to one another, among the plurality of subpixels SP can constitute one pixel P (or unit pixel). One pixel P can include, but is not limited to, a red subpixel, a green subpixel, a blue subpixel and a white subpixel. One pixel P can include three subpixels SP provided to emit light of different colors and disposed to be adjacent to one another. For example, one pixel P can include a red subpixel, a green subpixel and a blue subpixel.

Each of the plurality of subpixels SP includes a thin film transistor and a light emitting element layer E connected to the thin film transistor. Each of the plurality of subpixels can include a light emitting layer (or an organic light emitting layer) interposed between the pixel electrode and the reflective electrode.

Each of the subpixels SP supplies a predetermined current to the organic light emitting element in accordance with a data voltage of the data line when a gate signal is input from the gate line by using the thin film transistor. For this reason, the light emitting layer of each of the subpixels can emit light with a predetermined brightness in accordance with the predetermined current.

The plurality of subpixels SP according to one example can be disposed to be adjacent to each other in a first direction (e.g., X-axis direction). The first direction (X-axis direction) can be a horizontal direction based on FIG. 2. The horizontal direction can be a direction in which a gate line GL and/or a sensing line SL are disposed.

A second direction (e.g., Y-axis direction) is a direction crossing the first direction (X-axis direction), and can be a vertical direction based on FIG. 2. The vertical direction can be a direction in which a data line DL is disposed.

A third direction (e.g., Z-axis direction) is a direction crossing each of the first direction (X-axis direction) and the second direction (Y-axis direction), and can be a thickness direction of the display apparatus 100.

The plurality of subpixels SP can include a first subpixel SP1, a second subpixel SP2, a third subpixel SP3 and a fourth subpixel SP4 arranged adjacent to each other in the first direction (X-axis direction). For example, the first subpixel SP1 can be a red subpixel, the second subpixel SP2 can be a green subpixel, the third subpixel SP3 can be a blue subpixel and the fourth subpixel SP4 can be a white subpixel, but is not limited thereto. However, the arrangement order of the first subpixel SP1, the second subpixel SP2, the third subpixel SP3 and the fourth subpixel SP4 can be changed.

Each of the first to fourth subpixels SP1 to SP4 can include a light emission area EA and a circuit area CA. The light emission area EA can be disposed at one side (or an upper side) of a subpixel area, and the circuit area CA can be disposed at the other side (or a lower side) of the subpixel area. For example, the circuit area CA can be disposed at the lower side of the light emission area EA based on the second direction Y. The light emission areas EA of the first to fourth subpixels SP1 to SP4 can have different sizes (or areas).

The first to fourth subpixels SP1 to SP4 can be disposed to be adjacent to one another along the first direction (e.g., X-axis direction). For example, two data lines DL extended along the second direction (e.g., Y-axis direction) can be disposed in parallel with each other between the first subpixel SP1 and the second subpixel SP2 and between the third subpixel SP3 and the fourth subpixel SP4. A pixel power line EVDD extended along the first direction (X-axis direction) can be disposed between the light emission area EA and the circuit area CA of each of the first to fourth subpixels SP1 to SP4. The gate line GL and a sensing line SL can be disposed below the circuit area CA in the first direction (X-axis direction). The pixel power line EVDD extended along the second direction (Y-axis direction) can be disposed at one side of the first subpixel SP1 or the fourth subpixel SP4. A reference line RL extended along the second direction (Y-axis direction) can be disposed between the second subpixel SP2 and the third subpixel SP3. The reference line RL can be used as a sensing line for sensing a change of characteristics of a driving thin film transistor and/or a change of characteristics of the light emitting element layer, which is disposed in the circuit area CA, from the outside in a sensing driving mode of the pixel P.

In the display apparatus 100 according to one embodiment of the present disclosure, each of the plurality of subpixels SP can include the light extraction portion 140. The light extraction portion 140 can be formed on the overcoat layer 113 (shown in FIG. 3) to overlap the light emission area EA of the subpixel. The light extraction portion 140 can be formed on the overcoat layer 113 of the light emission area EA to have a curved (or uneven) shape, thereby changing a propagation path of light emitted from the light emitting element layer E to increase light extraction efficiency. For example, the light extraction portion 140 can be a non-flat portion, an uneven pattern portion, a micro lens portion, or a light scattering pattern portion.

The light extraction portion 140 can include a plurality of concave portions 141. The plurality of concave portions 141 can be formed to be concave inside the overcoat layer 113. For example, the plurality of concave portions 141 can be formed or configured to be concave from an upper surface 1131a of a first layer 1131 included in the overcoat layer 113. Therefore, the first layer 1131 can include a plurality of concave portions 141. The first layer 1131 can be disposed between the substrate 110 and the light emitting element layer E.

A second layer 1132 of the overcoat layer 113 can be disposed between the first layer 1131 and a light emitting element layer E (or a pixel electrode 114 shown in FIG. 3). The second layer 1132 according to one example can be formed to be wider than the pixel electrode 114 in a first direction (X-axis direction). Thus, a portion of the second layer 1132 can overlap the light emissive area EA, and the other portion of the second layer 1132 can be in contact with a portion of the bottom surface 120b while covering the inclined surface 120s of the pattern portion 120. For example, as shown in FIG. 3, the second layer 1132 can be extended from the light emission area EA to the first area A1 and thus can be in contact with a portion of the bottom surface 120b while covering the inclined surface 120s of the pattern portion 120. Since the pixel electrode 114 is disposed on an upper surface 1132a of the second layer 1132, the upper surface 1132a of the second layer 1132 can be provided to be flat.

Meanwhile, a refractive index of the second layer 1132 can be greater than that of the first layer 1131. Therefore, as shown in FIG. 4, a path of light emitted from a light emitting layer 116 and directed toward the substrate 110 can be changed toward the reflective portion 130 due to a difference in refractive indexes between the second layer 1132 and the first layer 1131 of the light extraction portion 140. Therefore, the light having a path formed in the reflective portion 130 by the light extraction portion 140 can be reflected in the reflective portion 130 and emitted toward the light emission area EA of the subpixel SP for emitting light. Hereinafter, the light reflected in the reflective portion 130 and emitted toward the substrate 110 will be defined as the reflective light.

The reflective light according to one example can include first reflective light L1 (shown in FIG. 3) reflected from the reflective portion 130 and emitted to the substrate 110 after being subjected to optical waveguide through total reflection between the pixel electrode 114 and the reflective electrode 117, second reflective light L2 (shown in FIG. 4) reflected from the reflective portion 130 and emitted to the substrate 110 after its path is changed by the light extraction portion 140, and third reflective light L3 (shown in FIG. 4) emitted from the light emission area EA and sequentially reflected to the line 150, the reflective portion 130 and the reflective electrode 117 and then emitted to the substrate 110.

The first reflective light L1 and the third reflective light L3 according to one example can be emitted from the light emission area EA. The second reflective light L2 can be emitted from a position spaced apart from the light emission area EA. For example, the second reflective light L2 can be emitted from the non-light emission area NEA or the peripheral area. In case of a general display apparatus, since a pixel driving line for pixel driving is disposed between the banks, a portion of the light emitted from the light emission area is covered by the pixel driving line and thus cannot be emitted toward the substrate. However, in the display apparatus 100 according to one embodiment of the present disclosure, a first data line DL1 disposed in the first area A1 is formed of a reflective line, so that light directed toward the first data line DL1 can be reflected by the first data line DL1 and emitted toward the substrate 110 through the reflective portion 130 and the reflective electrode 117. Therefore, the display apparatus 100 according to one embodiment of the present disclosure can perform light extraction by using the reflective line, thereby maximizing light extraction efficiency of light that is emitted.

Meanwhile, as shown in FIGS. 4 and 5, the second reflective light L2 can be emitted toward the substrate 110 from the position spaced apart from the light emission area EA, but is not limited thereto. The first reflective light L1 can be emitted toward the substrate 110 from the position spaced apart from the light emission area EA.

In the display apparatus 100 according to one embodiment of the present disclosure, since the pattern portion 120 is disposed to surround the light emission area EA, at least a portion of the reflective portion 130 on the pattern portion 120 can be disposed to surround the light emission area EA. Therefore, the reflective light can be emitted toward the substrate 110 from the position spaced apart from the light emission area EA while surrounding at least a portion of the light emission area EA. As shown in the image of FIG. 5, it can be seen that the reflective light is emitted between the subpixels SP and from a corner portion of each subpixel SP. The corner portion can be an edge portion. In case of a general display apparatus, since the corner portion of the light emission area is bent at a predetermined angle, light emission efficiency can be reduced as compared with a central portion of the light emission area. In contrast, in the display apparatus 100 according to one embodiment of the present disclosure, since the reflective portion 130 is disposed in the non-light emission area surrounding the corner portion of the light emission area even though the corner portion of the light emission area is bent at a predetermined angle, light extraction can be performed, whereby the overall light emission efficiency can be increased.

Meanwhile, since FIG. 5 is exemplary, the reflective light can be emitted from the position spaced apart from the light emission area EA while surrounding the entire light emission area EA. Therefore, in the display apparatus 100 according to one embodiment of the present disclosure, since light dissipated by optical waveguide and/or light dissipated by the interface total reflection can be emitted from the non-light emission area NEA in the form of reflective light through the reflective portion 130 surrounding the light emission area EA, light extraction efficiency can be improved and the overall light emission efficiency can be increased.

Further, in the display apparatus 100 according to one embodiment of the present disclosure, since light, which cannot be emitted by being covered by a line, can be emitted to the outside through the reflective line 150 disposed in the non-light emission area NEA, light extraction efficiency can be maximized.

Hereinafter, a structure of each of the plurality of subpixels SP will be described in detail.

Referring to FIG. 3, the display apparatus 100 according to one embodiment of the present disclosure can further include a buffer layer BL, a circuit element layer, a thin film transistor, a pixel electrode 114, a bank 115, a light emitting layer 116, a reflective electrode 117, an encapsulation layer 118 and a color filter CF.

In more detail, each of the subpixels SP according to one embodiment can include a circuit element layer provided on an upper surface of a buffer layer BL, including a gate insulating layer, an interlayer insulating layer 111 and a passivation layer 112, an overcoat layer 113 provided on the circuit element layer, a pixel electrode 114 provided on the overcoat layer 113, a bank 115 covering an edge of the pixel electrode 114, a light emitting layer 116 on the pixel electrode 114 and the bank 115, a reflective electrode 117 on the light emitting layer 116, and an encapsulation layer 118 on the reflective electrode 117.

The thin film transistor for driving the subpixel SP can be disposed on the circuit element layer. The pixel electrode 114, the light emitting layer 116 and the reflective electrode 117 can be included in the light emitting element layer E.

The buffer layer BL can be formed between the substrate 110 and the gate insulating layer to protect the thin film transistor. The buffer layer BL can be disposed on the entire surface (or front surface) of the substrate 110. The pixel power line EVDD for pixel driving can be disposed between the buffer layer BL and the substrate 110. The buffer layer BL can serve to block diffusion of a material contained in the substrate 110 into a transistor layer during a high temperature process of a manufacturing process of the thin film transistor.

The thin film transistor (or a drive transistor) according to an example can include an active layer, a gate electrode, a source electrode, and a drain electrode. The active layer can include a channel area, a drain area and a source area, which are formed in a thin film transistor area of a circuit area of the subpixel SP. The active layer can be formed of a semiconductor material.

The gate insulating layer can be formed on the channel area of the active layer. The interlayer insulating layer 111 can be formed to partially overlap the gate electrode and the drain area and source area of the active layer. As shown in FIG. 3, the interlayer insulating layer 111 can be formed over the entire subpixel SP.

The source electrode can be electrically connected to the source area of the active layer through a source contact hole provided in the interlayer insulating layer 111 overlapped with the source area of the active layer. The drain electrode can be electrically connected to the drain area of the active layer through a drain contact hole provided in the interlayer insulating layer 111 overlapped with the drain area of the active layer.

A passivation layer 112 can be provided on the substrate 110 to cover a pixel area. The passivation layer 112 covers a drain electrode, a source electrode and a gate electrode of a thin film transistor and a buffer layer BL. The plurality of lines 150 can be disposed between the passivation layer 112 and an interlayer insulating layer 111. For example, the plurality of lines 150 can include a first data line DL1 for driving the first subpixel SP1, a second data line DL2 for driving the second subpixel SP2, a third data line DL3 for driving the third subpixel SP3 and a fourth data line DL4 for driving the fourth subpixel SP4. The plurality of lines 150 can further include a pixel power line EVDD and a reference line RL. The reference line RL can be disposed at a position symmetrical to the pixel power line EVDD based on the light emission area EA or a similar position symmetrical to the pixel power line EVDD.

Meanwhile, as shown in FIG. 3, the pixel power line EVDD and the first and second data lines DL1 and DL2 can be disposed in the non-light emission area NEA without covering the light emission area EA. The passivation layer 112 can be formed over a circuit area and the light emission area. The passivation layer 112 can be omitted. A color filter CF can be disposed on the passivation layer 112.

The overcoat layer 113 can be provided on the substrate 110 to cover the passivation layer 112 and the color filter CF. When the passivation layer 112 is omitted, the overcoat layer 113 can be provided on the substrate 110 to cover the circuit area. The overcoat layer 113 can be formed in the circuit area CA in which the thin film transistor is disposed and the light emission area EA. In addition, the overcoat layer 113 can be formed in the other non-display area NDA except a pad area PA of the non-display area NDA and the entire display area DA. For example, the overcoat layer 113 can include an extension portion (or an enlarged portion) extended or enlarged from the display area DA to the other non-display area NDA except the pad area PA. Therefore, the overcoat layer 113 can have a size relatively wider than that of the display area DA.

The overcoat layer 113 according to one example can be formed to have a relatively thick thickness, thereby providing a flat surface on the display area DA and the non-display area NDA. For example, the overcoat layer 113 can be made of an organic material such as photo acryl, benzocyclobutene, polyimide and fluorine resin.

The overcoat layer 113 formed in the display area DA (or the light emission area EA) can include a plurality of concave portions 141. The plurality of concave portions 141 are the elements of the light extraction portion 140 for increasing light efficiency of the light emission area EA, and can be formed inside the overcoat layer 113. In detail, as shown in FIG. 3, the plurality of concave portions 141 can be formed in a concave shape on the first layer 1131 of the overcoat layer 113. The plurality of concave portions 141 are provided to be connected to each other so that an embossed shape can be formed in the first layer 1131.

The display apparatus 100 according to one embodiment of the present disclosure can be provided with a plurality of concave portions 141 so as to correspond to the light emission area EA, thereby refracting light, which is directed toward the adjacent subpixel, toward the subpixel for emitting light. Therefore, the display apparatus 100 according to one embodiment of the present disclosure can increase a luminance retention rate due to the plurality of concave portions 141 provided in the light emission area EA (or opening).

The second layer 1132 having a refractive index higher than that of the first layer 1131 can be formed on the first layer 1131. A path of the light, which is directed toward the adjacent subpixel SP, among the light emitted from the light emitting element layer E can be changed toward the reflective portion 130 in accordance with a difference in the refractive index between the second layer 1132 and the first layer 1131. The second layer 1132 can be provided to cover the embossed shape of the first layer 1131 and thus the upper surface 1132a can be provided to be flat.

The pixel electrode 114 is formed on the upper surface 1132a of the second layer 1132 so that the pixel electrode 114 can be provided to be flat, and the light emitting layer 116 and the reflective electrode 117, which are formed on the pixel electrode 114, can be provided to be also flat. Since the pixel electrode 114, the light emitting layer 116, the reflective electrode 117, for example, the light emitting element layer E is provided to be flat in the light emission area EA, a thickness of each of the pixel electrode 114, the light emitting layer 116 and the reflective electrode 117 in the light emission area EA can be uniformly formed. Therefore, the light emitting layer 116 can be uniformly emitted without deviation in the light emission area EA.

The plurality of concave portions 141 can be formed on the first layer 1131 through a photo process using a mask having an opening portion and then a pattern (or etching) or ashing process after the first layer 1131 is coated to cover the passivation layer 112 and the color filter CF. The plurality of concave portions 141 can be formed in an area overlapped with the color filter CF and/or an area that is not overlapped with the bank 115 of the non-light emission area NEA, but are not limited thereto. A portion of the plurality of concave portions 141 can be formed to overlap the bank 115.

Referring back to FIG. 3, the color filter CF disposed in the light emission area EA can be provided between the plurality of lines 150 and the pattern portion 120 or between the substrate 110 and the overcoat layer 113. Therefore, the color filter CF can be provided between the plurality of lines 150, for example, between the pixel power line EVDD and the reflective portion 130 or between the first data line DL1 and the pattern portion 120. The color filter CF can include a red color filter (or a first color filter) CF1 for converting white light emitted from the light emitting layer 116 into red light, a blue color filter (or a second color filter) CF2 for converting white light into blue light, and a green color filter (or a third color filter) CF3 for converting white light into green light. The first color filter CF1 can be provided in the first subpixel SP1, the second color filter CF2 can be provided in the third subpixel SP3, and the third color filter CF3 can be provided in the fourth subpixel SP4. The second subpixel, which is a white subpixel, may not include a color filter because the light emitting layer 116 emits white light. The color filter CF according to one example can be formed to be extended from the light emission area EA of each of the plurality of subpixels SP to the second area A2 by passing through the first area A1.

Meanwhile, as in a left portion of FIG. 3, in the display apparatus 100 according to one embodiment of the present disclosure, color filters having different colors can be provided to partially overlap each other in the boundary portion of the plurality of subpixels SP, for example, in the second area A2 between a first area A1 of a fourth subpixel SP4′ and the first area A1 of the first subpixel SP1 of adjacent pixels. In this case, in the display apparatus 100 according to one embodiment of the present disclosure, since light emitted from each subpixel SP can be prevented from being emitted to the adjacent subpixel SP due to the color filters overlapped with each other in the boundary portion of the subpixels SP, color mixture between the subpixels SP can be avoided. For example, as shown in FIG. 3, the first color filter CF1 and a third color filter CF3′ of the fourth subpixel SP4′, which is adjacent thereto, can overlap each other in the second area A2 overlapped with the boundary portion between the first subpixel SP1 and the fourth subpixel SP4′.

In a right portion of FIG. 3, for example, between the first subpixel SP1 and the second subpixel SP2, since the second subpixel SP2 is the white subpixel that does not include a color filter, only the first color filter CF1 can be formed to partially cover the second area A2 by passing through the first area A1 of the first subpixel SP1. In this case, the first color filter CF1 can partially overlap a line AL1 disposed in the first area A1, for example, the first data line DL1, and/or a line AL2 disposed in the second area A2, for example, the second data line DL2. As shown in FIG. 3, a line AL3 disposed over the first area A1 and the second area A2 can be the pixel power line EVDD. In the display apparatus 100 according to one embodiment of the present disclosure, the line AL1 disposed in the first area A1 of the plurality of lines 150 can be a reflective line. Therefore, as shown in FIG. 4, light, which is directed toward the first data line DL1, among the light emitted from the light emission area EA can be reflected by the first data line DL1 and directed toward the reflective portion 130. The light directed toward the reflective portion 130 can be reflected by the reflective portion 130 (or the reflective electrode 117) disposed in the first area A1 and emitted to the light emission area EA of the subpixel SP for emitting light. Therefore, the display apparatus 100 according to one embodiment of the present disclosure can further increase light efficiency in the light emission area EA.

As a result, in the display apparatus 100 according to one embodiment of the present disclosure, the first subpixel SP1 can include a color filter CF disposed between the reflective line and the pattern portion 120, and the color filter CF can have a structure that does not overlap the first area A1 of the second subpixel SP2 for emitting white light. Such a structure can be also applied between the subpixels SP for emitting colored light.

Meanwhile, the second data line DL2 can be disposed in the second area A2, unlike the first data line DL1. When the second data line DL2 is disposed in the first area A1 of the second subpixel SP2, the light reflected by the reflective portion 130 of the second subpixel SP2 is blocked (or interfered) by the second data line DL2, whereby emission efficiency is lowered. Therefore, the second data line DL2 for driving the white subpixel SP2 can be disposed in the second area A2 between the first area A1 of the second subpixel SP2 and the first area A1 of the first subpixel SP1. Additionally, the second data line DL2 disposed in the second area A2 may not be provided as a reflective line. For example, the second data line DL2 can be provided as a non-reflective line. If the second data line DL2 is provided as a reflective line, a portion of the light emitted from the first subpixel SP1 can be reflected by the second data line DL2 and emitted toward the second subpixel SP2 to generate color mixture. In addition, the second data line DL2 can be provided to partially (at least partially) overlap the first color filter CF1. When the second data line DL2 does not overlap the first color filter CF1, light leakage can occur between the second data line DL2 and the first color filter CF1. Therefore, in the display apparatus 100 according to one embodiment of the present disclosure, the second data line DL2 is provided to be disposed in the second area A2 between the first area A1 of the first subpixel SP1 and the second area A2 of the second subpixel SP2, thereby preventing color mixing with the first subpixel SP1 without interfering with light extraction efficiency of the second subpixel SP2. Further, in the display apparatus 100 according to one embodiment of the present disclosure, the second data line DL2 can be provided to partially overlap the first color filter CF1 in the second area A2, thereby preventing light leakage from occurring when the first subpixel SP1 emits light.

Referring back to FIG. 3, the pixel electrode 114 of the subpixel SP can be formed on the overcoat layer 113. The pixel electrode 114 can be connected to the drain electrode or the source electrode of the thin film transistor through a contact hole passing through the overcoat layer 113 and the passivation layer 112. As shown in FIG. 3, the pixel electrode 114 can be provided to be narrower than the second layer 1132, but is not limited thereto. The pixel electrode 114 can be provided to be wider than the second layer 1132 in accordance with a cross-sectional position. For example, when the pixel electrode 114 is provided to be wider than the second layer 1132, an edge portion of the pixel electrode 114 can be connected to the drain electrode or the source electrode in the circuit area CA. In this case, the edge portion of the pixel electrode 114 can be covered by the bank 115. The pixel electrode 114 can be made of at least one of a transparent metal material or a semi-transmissive metal material.

Because the display apparatus 100 according to an embodiment of the present disclosure is configured as the bottom emission type, the pixel electrode 114 can be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 can include MoTi. The pixel electrode 114 can be a first electrode or an anode electrode.

The bank 115 is an area from which light is not emitted, and can be provided to surround each of the light emitting portions (or concave portions 141 of the light extraction portion 140, shown in FIG. 3) of each of the plurality of subpixels SP. For example, the bank 115 can partition (or define) the concave portions 141 of each of the light emitting portion or the subpixels SP. The light emitting portion can mean a portion with which the pixel electrode 114 and the reflective electrode 117 are in contact with each of an upper surface and a lower surface of the light emitting layer 116 with the light emitting layer 116 interposed therebetween.

The bank 115 can be formed to cover the edge of each pixel electrode 114 of each of the subpixels SP and expose a portion of each of the pixel electrodes 114. For example, the bank 115 can partially cover the pixel electrode 114. Therefore, the bank 115 can prevent the pixel electrode 114 and the reflective electrode 117 from being in contact with each other at the end of each pixel electrode 114. The exposed portion of the pixel electrode 114, which is not covered by the bank 115, can be included in the light emitting portion (or the light emission area). As shown in FIG. 3, the light emitting portion can be formed on the plurality of concave portions 141, and thus the light emitting portion (or the light emission area EA) can overlap the concave portions 141 in a thickness direction of the substrate 110.

As shown in FIGS. 3 and 4, the bank 115 according to one example can be disposed in the non-light emission area NEA of each of the plurality of subpixels SP. The bank 115 of each of the plurality of subpixels SP can be disposed in the first area A1. Therefore, as shown in FIGS. 3 and 4, the banks 115 of the plurality of subpixels SP can be spaced apart from each other based on the second area A2. As the banks 115 of the subpixels SP are spaced apart from the second area A2, the light emitting layer 116 and the reflective electrode 117 (or the reflective portion 130) can be disposed to be closer to the substrate 110 in the second area A2. In other words, as the bank 115 of each subpixel SP is not formed in the second area A2, the light emitting layer 116 and the reflective electrode 117 (or the reflective portion 130) can be disposed to be deeper toward the substrate 110 in the second area A2 than the first area A1. Therefore, since an area of the curved surface 132 of the reflective portion 130 can be increased, a reflective area for reflecting light toward the adjacent subpixel SP can be increased, whereby light extraction efficiency can be improved.

After the bank 115 is formed, the light emitting layer 116 can be formed to cover the pixel electrode 114 and the bank 115. Therefore, the bank 115 can be provided between the pixel electrode 114 and the light emitting layer 116. The bank 115 can be expressed as the term of a pixel defining layer. The bank 115 according to one example can be made of an organic material or an inorganic material. The bank 115 can be formed to have the same or similar thickness along the profile of the pattern portion 120 (or the second layer 1132).

Referring again to FIG. 3, the light emitting layer 116 can be formed on the pixel electrode 114 and the bank 115. The light emitting layer 116 can be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the light emitting layer 116 can emit light. The light emitting layer 116 can be formed of a plurality of subpixels SP and a common layer provided on the bank 115.

The light emitting layer 116 according to an embodiment can be provided to emit white light. The light emitting layer 116 can include a plurality of stacks which emit lights of different colors. For example, the light emitting layer 116 can include a first stack, a second stack, and a charge generating layer (CGL) provided between the first stack and the second stack. The light emitting layer can be provided to emit the white light, and thus, each of the plurality of subpixels SP can include a color filter CF suitable for a corresponding color.

The reflective electrode 117 can be formed on the light emitting layer 116. The reflective electrode 117 according to one example can include a metal material. The reflective electrode 117 can reflect the light emitted from the light emitting layer 116 in the plurality of subpixels SP toward the lower surface of the substrate 110. Therefore, the display apparatus 100 according to one embodiment of the present disclosure can be implemented as a bottom emission type display apparatus.

The display apparatus 100 according to one embodiment of the present disclosure is a bottom emission type and has to reflect light emitted from the light emitting layer 116 toward the substrate 110, and thus the reflective electrode 117 can be made of a metal material having high reflectance. The reflective electrode 117 according to one example can be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy can be an alloy such as silver (Ag), palladium (Pd) and copper (Cu). The reflective electrode 117 can be expressed as terms such as a second electrode, a cathode electrode and a counter electrode.

Meanwhile, in the display apparatus 100 according to one embodiment of the present disclosure, the reflective portion 130 can be a portion of the reflective electrode 117. Therefore, the reflective portion 130 can reflect light, which is directed toward the adjacent subpixel SP, toward the light emission area EA of the subpixel SP for emitting light. Since the reflective portion 130 is a portion of the reflection electrode 117, as shown in FIG. 3, the reflective portion 130 can be denoted by a reference numeral 117a. In the present disclosure, the reflective portion 130 can mean the reflective electrode 117 that overlaps the pattern portion 120 (or the first area A1 and the second area A2). In particular, the reflective portion 130 can mean the reflective electrode 117 formed of an inclined or curved surface while overlapping the pattern portion 120. Therefore, the reflective portion 130 can reflect light that is directed toward the adjacent subpixel SP, and/or light that is dissipated through total reflection between interfaces, and/or the light reflected on the line 150 toward the light emission area EA and/or the non-emission area NEA of the subpixel SP for emitting light.

The encapsulation layer 118 is formed on the reflective electrode 117. The encapsulation layer 118 serves to prevent oxygen or moisture from being permeated into the light emitting layer 116 and the reflective electrode 117. To this end, the encapsulation layer 118 can include at least one inorganic film and at least one organic film. Meanwhile, as shown in FIG. 3, the encapsulation layer 118 can be disposed not only in the light emission area EA but also in the non-light emission area NEA. The encapsulation layer 118 can be disposed between the reflective electrode 117 and an opposing substrate 200.

Hereinafter, the pattern portion 120 and the reflective portion 130 of the display apparatus 100 according to one embodiment of the present disclosure will be described in more detail with reference to FIGS. 1 to 6.

In the display apparatus 100 according to one embodiment of the present disclosure, the pattern portion 120 can be provided near the light emission area EA (or near the non-light emission area NEA) and the reflective portion 130 can be provided on the pattern portion 120 in order to prevent light extraction efficiency from being reduced as some of the light emitted from the light emitting element layer is not discharged to the outside due to a disconnection of line and/or total reflection on an interface between the light emitting element layer and the electrode and/or an interface between the substrate and the air layer.

For example, as shown in FIG. 3, the pattern portion 120 can be formed to be concave in the first layer 1131 of the overcoat layer 113. As shown in FIG. 3, the pattern portion 120 can be disposed near the non-light emission area NEA or the light emission area EA. For example, the pattern portion 120 can be disposed to surround the light emission area EA while being adjacent to the light extraction portion 140. The pattern portion 120 can be formed in the non-light emission area NEA together with the plurality of concave portions 141 when the plurality of concave portions 141 are formed in the light emission area EA. The pattern portion 120 can include a bottom surface 120b and an inclined surface 120s.

The bottom surface 120b of a pattern portion 120 according to one example can be extended from the inclined surface 120s formed in the first area A1 and the formed to reach the second area A2. The bottom surface 120b of the pattern portion 120 is a surface formed closest to the substrate 110 in the pattern portion 120, and can be disposed to be closer to the substrate 110 (or the upper surface of the substrate) than the pixel electrode 114 (or the lower surface of the pixel electrode 114) in the light emission area EA. Therefore, as shown in FIG. 3, the bottom surface 120b of the pattern portion 120 can be provided at a depth equal to or similar to that of each of the plurality of concave portions 141. However, when the depth of the pattern portion 120 is lower than that of the concave portion 141, the area of the reflective portion 130 is reduced, whereby light extraction efficiency can be reduced. Therefore, in the display apparatus 100 according to one embodiment of the present disclosure, the depth of the pattern portion 120 can be equal to or deeper than that of the concave portion 141.

The inclined surface 120s of the pattern portion 120 can be formed in the first area A1 and disposed between the bottom surface 120b and the light extraction portion 140. Therefore, the inclined surface 120s of the pattern portion 120 can be provided to surround the light emission area EA or the plurality of concave portions 141. As shown in FIG. 3, the inclined surface 120s can be connected to the bottom surface 120b. The inclined surface 120s can form a predetermined angle with the bottom surface 120b. For example, the angle formed by the inclined surface 120s and the bottom surface 120b can be an obtuse angle. Therefore, a width of the pattern portion 120 can be gradually reduced in a direction (or the third direction (Z-axis direction)) toward the substrate 110 from an opposing substrate 200 (or the reflective portion 130). As the obtuse angle is formed between the inclined surface 120s and the bottom surface 120b, the light emitting element layer E (or the light emitting element layer E including the reflective portion 130), which includes the second layer 1132, the bank 115 and the reflective portion 130, which are formed in a subsequent process, can be formed to be concave along the profile of the pattern portion 120. Therefore, the light emitting element layer E can be formed to be concave in the pattern portion 120 formed to be concave in the non-light emission area NEA (or the peripheral area). The light emitting element layer E formed to be concave in the pattern portion 120 can mean that at least one of the pixel electrode 114, the light emitting layer 116 or the reflective electrode 117 is included therein.

As shown in FIG. 2, the pattern portion 120 can be provided to surround the light emission area EA. As the pattern portion 120 is provided to surround the light emission area EA, at least a portion of the reflective portion 130 disposed on the pattern portion 120 can be provided to surround the light emission area EA. Therefore, in the display apparatus 100 according to one embodiment of the present disclosure, since light can be extracted even from the non-light emission area NEA near the light emission area EA, overall light efficiency can be improved. Therefore, the display apparatus 100 according to one embodiment of the present disclosure can have the same light emission efficiency or more improved light emission efficiency even with low power as compared with a general display apparatus having no pattern portion 120 and reflective portion 130, whereby overall power consumption can be reduced.

In addition, the display apparatus 100 according to one embodiment of the present disclosure can allow the light emitting element layer E to emit light even with low power, thereby improving lifespan of the light emitting element layer E.

Referring back to FIG. 2, the pattern portion 120 can include a first pattern line 121 disposed in the first direction (X-axis direction) between the circuit area CA and the light emission area EA and a second pattern line 122 disposed in the second direction (Y-axis direction) crossing the first direction (X-axis direction). Referring to FIG. 2, the first pattern line 121 can mean the pattern portion 120 disposed in a horizontal direction, and the second pattern line 122 can mean the pattern portion 120 disposed in a vertical direction.

The first pattern line 121 can include a bottom surface and an inclined surface. The second pattern line 122 can include a bottom surface and an inclined surface. Since each of the bottom surface and the inclined surface of the first pattern line 121 and each of the bottom surface and the inclined surface of the second pattern line 122 are the same as each of the bottom surface 120b and the inclined surface 120s of the pattern portion 120, their description thereof is omitted. The first pattern line 121 and the second pattern line 122 can be connected to one in the non-light emission area NEA (or the peripheral area) to surround the light emission area EA. The first pattern line 121 can be disposed between the subpixels SP for emitting light of the same color. The second pattern line 122 can be disposed between the subpixels SP for emitting light of different colors.

Since the second pattern line 122 is disposed between the subpixels SP for emitting light of different colors, the reflective portion 130 on the second pattern line 122 can prevent light of different colors from being emitted to other adjacent subpixels SP. Therefore, the display apparatus 100 according to the present disclosure can prevent color mixture (or color distortion) between the subpixels SP for emitting light of different colors, thereby improving color purity.

The second layer 1132 of the overcoat layer 113 can be further extended from the light emission area EA to the non-light emission area NEA to partially cover the inclined surface 120s of the pattern portion 120. For example, a portion of the second layer 1132 can extend from the light emission area EA to the first area A1 to cover the inclined surface 120s of the pattern portion 120. Therefore, as shown in FIG. 3, an end 1132c of the second layer 1132 can be in contact with the bottom surface 120b of the pattern portion 120. In this case, the end 1132c of the second layer 1132 can be in contact with only a portion of the bottom surface 120b. When the second layer 1132 entirely covers the bottom surface 120b, the depth of the reflective portion 130 formed on the pattern portion 120 can be relatively lowered, thereby reducing reflective efficiency. Therefore, in the display apparatus 100 according to one embodiment of the present disclosure, the second layer 1132 is provided to be in contact with only a portion of the bottom surface 120b without entirely covering the bottom surface 120b of the pattern portion 120 and thus the reflective portion 130 formed in a subsequent process can be formed to be close to the bottom surface 120b, whereby reflective efficiency can be improved.

As shown in FIG. 3, the bank 115 can be extended to cover the inclined surface 1132b of the second layer 1132 covering the inclined surface 120s of the pattern portion 120 while covering the edge of the pixel electrode 114. Therefore, the bank 115 can be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency can be reduced. Therefore, as shown in FIG. 3, each of the second layer 1132 and the bank 115 on the bottom surface 120b of the pattern portion 120 can be discontinuously provided. For example, each of the second layer 1132 and the bank 115 can be disconnected on the bottom surface 120b of the pattern portion 120. As a result, in the display apparatus 100 according to one embodiment of the present disclosure, the bank 115 is provided to be in contact with only a portion of the bottom surface 120b without entirely covering the bottom surface 120b, so that the reflective portion 130 formed in a subsequent process can be formed to be close to the bottom surface 120b, whereby reflective efficiency can be improved.

Since the bank 115 is provided to be in contact with only a portion of the bottom surface 120b of the pattern portion 120, the bank 115 can be disconnected from the pattern portion 120 (or the second area (A2)) as shown in FIGS. 3 and 4. Since FIG. 3 is a cross-sectional view of FIG. 2, the pattern portion 120 from which the bank 115 is disconnected can be the second pattern line 122. Therefore, the bank 115 can be disconnected from the second pattern line 122. As the bank 115 is disconnected from the second pattern line 122, the reflective portion 130 disposed on the second pattern line 122 can be disposed to be close to the bottom surface of the second pattern line. Therefore, the reflective portion 130 can be formed as deep as possible in the second pattern line 122 as compared with the case that the bank is not disconnected from the second pattern line, and thus reflective efficiency can be improved. Since the second pattern line 122 is disposed between the subpixels SP for emitting light of different colors, prevention of color mixture or color distortion between the subpixels SP for emitting light of different colors can be maximized. As shown in FIG. 2, since the second pattern line 122 is disposed between the subpixels SP for emitting light of different colors, the second layer 1132, the bank 115, the light emitting layer 116 and the reflective portion 130 (or the reflective electrode 117) can be provided to be symmetrical based on the center of the pattern portion 120 (or the second pattern line 122).

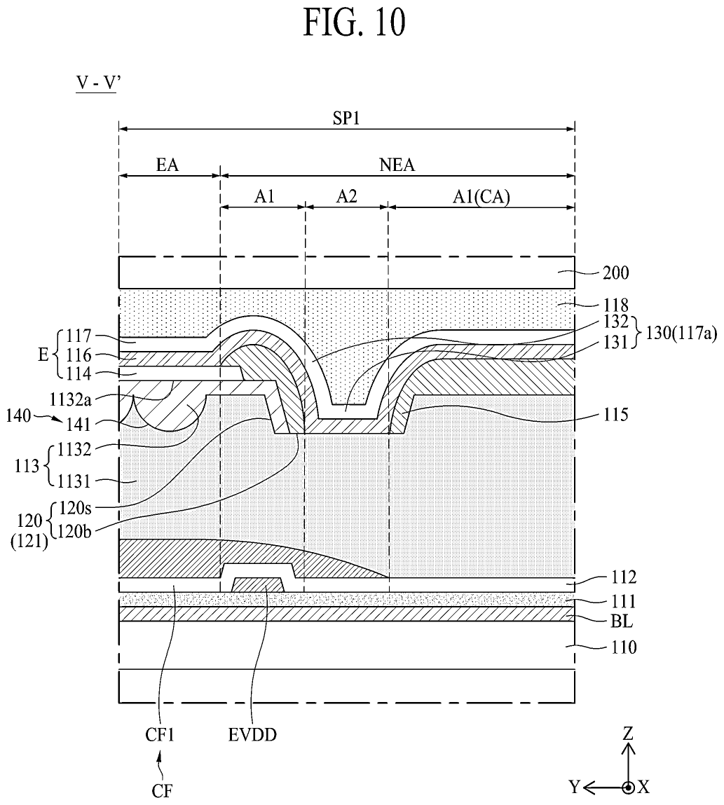

The first pattern line 121 can be disposed between the subpixels SP for emitting light of the same color. Therefore, as shown in FIG. 10 to be described later, the second layer 1132 can be formed only to the first area A1 adjacent to the light emission area EA, and the second layer 1132 may not be formed on an opposite side of the light emission area EA based on the first pattern line 121. As a result, since the first pattern line 121 is disposed between the subpixels SP for emitting light of the same color, the bank 115, the light emitting layer 116 and the reflective portion 130 (or the reflective electrode 117) can be provided to be asymmetrical based on the center of the pattern portion 120 (or the first pattern line 121) as shown in FIG. 10.

Referring back to FIG. 2, the first pattern line 121 can be disposed between the circuit area CA and the light emission area EA. The pixel electrode 114 can be extended to the circuit area CA along a profile of the first pattern line 121. Therefore, the edge of the pixel electrode 114 disposed in the circuit area CA can be in contact with the source electrode or the drain electrode of the thin film transistor.

FIG. 5 is an image illustrating light extraction characteristics of a non-light emission area of a display apparatus 100 according to one embodiment of the present disclosure, and shows a state that all of four subpixels SP emit light. Among the light emitted from the light emission area EA, the light that is directed toward an adjacent subpixel SP through total reflection between the interfaces or directed toward the adjacent subpixel SP due to its path change by the light extraction portion and/or the light reflected by the line 150 and directed toward the adjacent subpixel SP can be reflected in the reflective portion 130 formed to be concave on the pattern portion 120. Therefore, as shown in FIG. 5, at least some of the reflective light reflected by the reflective portion 130 can be emitted from the position spaced apart from the light emission area EA while surrounding the light emission area EA of each of the subpixels SP. Therefore, in the display apparatus 100 according to one embodiment of the present disclosure, since light dissipated by optical waveguide and/or light dissipated by the interface total reflection and/or light that is blocked by line and extinguished can be emitted from the non-light emission area NEA in the form of reflective light through the reflective portion 130 surrounding at least a portion of the light emission area EA, light extraction efficiency can be improved and the overall light emission efficiency can be increased.

Further, since light can be extracted even from the non-light emission area NEA due to the reflective portion 130 provided in the non-light emission area NEA, the display apparatus 100 according to one embodiment of the present disclosure can have the same light emission efficiency or more improved light emission efficiency even with low power as compared with a general display apparatus having no reflective portion, whereby overall power consumption can be reduced.

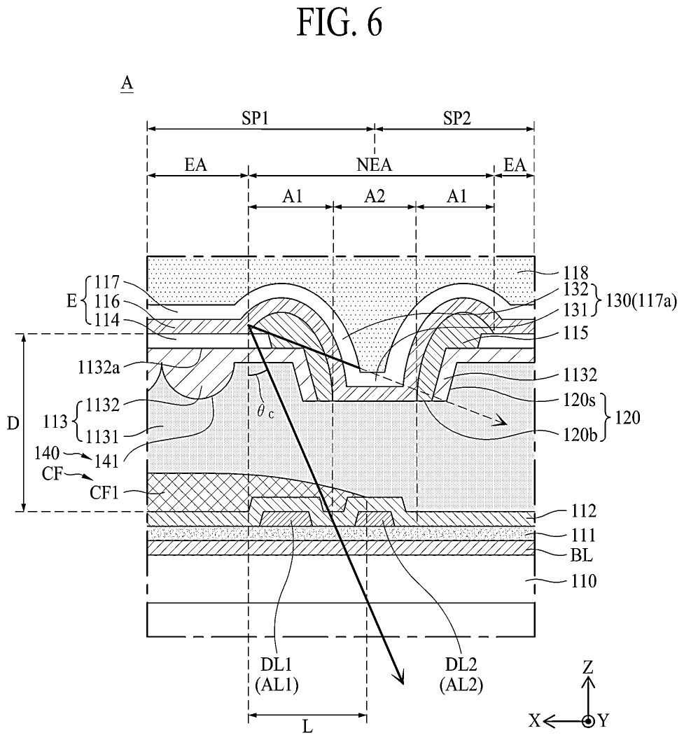

FIG. 6 is an enlarged view illustrating a portion A shown in FIG. 3, illustrating a color filter disposed in a non-light emission area.

Referring to FIG. 6, in the display apparatus 100 according to one embodiment of the present disclosure, each of the plurality of subpixels SP can include a color filter CF. However, since the light emitting layer 116 emits white light, the color filter CF may not be disposed in the second subpixel SP2. Therefore, the first subpixel SP1, the third subpixel SP3 and the fourth subpixel SP4 can include a first color filter CF1, a second color filter CF2 and a third color filter CF3, respectively.

The color filter CF according to one example can be formed up to at least a portion of the second area A2 by passing through the first area A1 in the light emission area EA of each of the plurality of subpixels SP. This is to prevent color mixture from occurring between the plurality of subpixels SP or prevent light leakage from occurring in the boundary portion (or the boundary line) between the plurality of subpixels SP.

In the display apparatus 100 according to one embodiment of the present disclosure, a distance L from an end of the color filter CF to an end of the light emission area EA of each of the plurality of subpixels SP can be provided to satisfy the following relationship:

L≥D*tan θc,

where D is a distance from the light emitting layer 116 to a lower surface (or a boundary surface between the passivation layer 112 and the color filter CF) of the color filter CF, and θc can be a threshold angle at which the light emitted from the light emitting layer 116 is totally reflected on the upper surface of the substrate 110.

Alternatively, in the display apparatus 100 according to one embodiment of the present disclosure, the distance L from the end of the color filter CF to the end of the light emission area EA of each of the plurality of subpixels SP can be provided to satisfy the following relationship:

L≥D*tan(arcsin(n1/n2)),

where D is a distance from the light emitting layer 116 to the lower surface (or the boundary surface between the passivation layer 112 and the color filter CF) of the color filter CF, n1 is a refractive index of the light emitting layer 116, and n2 can be a refractive index of the substrate 110 (or the passivation layer 112).

For example, in the display apparatus 100 according to one embodiment of the present disclosure, the distance L from the end of the color filter CF to the end of the light emission area EA of each of the plurality of subpixels SP can be equal to or greater than a value obtained by multiplying the distance D from the light emitting layer 116 to the lower surface (or the boundary surface between the passivation layer 112 and the color filter CF) of the color filter CF and tan θc (or tan(arcsin(n1/n2))).

Therefore, in the display apparatus 100 according to one embodiment of the present disclosure, as shown in FIG. 6, the light emitted from the subpixel SP for emitting light can be emitted to the first area A1 or the second area A2 of the subpixel SP for emitting light, through the color filter CF disposed in the first area A1 or the second area A2. As a result, in the display apparatus 100 according to one embodiment of the present disclosure, since the light having a color of the subpixel SP for emitting light can be emitted even in the first area A1 or the second area A2 of the non-light emission area NEA, overall light emission efficiency (or light extraction efficiency) can be increased. Further, in the display apparatus 100 according to one embodiment of the present disclosure, since the distance from the light emission area EA to the end of the color filter CF can be determined through the above equation, color mixture with adjacent subpixels SP can be avoided, and light leakage can be also avoided.

In the display apparatus 100 according to one embodiment of the present disclosure, a distance (or width) from a portion (the light emission area EA) of the color filter CF to the end of the color filter CF can be determined by the above equation, and the color filter CF can be a color filter CF of a colored subpixel (for example, the first subpixel SP1 or the third subpixel SP3) adjacent to the white subpixel, for example, the second subpixel SP2. This is because that the second data line DL2 for driving the second subpixel SP2 is not disposed in the first area A1 of the second subpixel SP2 but disposed in the second area A2 in order to prevent light extraction attenuation of the second subpixel SP. Therefore, as shown in FIG. 6, the first color filter CF1 of the first subpixel SP1 adjacent to the second subpixel SP2, which is the white subpixel, can overlap at least a portion of the second data line DL2 through the above equation. Therefore, the display apparatus 100 according to one embodiment of the present disclosure can prevent light extraction attenuation of the second subpixel SP2, and at the same time can prevent color mixture from occurring between the first subpixel SP1 and the second subpixel SP2 and prevent light leakage from occurring in the boundary portion between the first subpixel SP1 and the second subpixel SP2.

Meanwhile, as shown in FIG. 6, the reflective portion 130 can be positioned to be close to the bottom surface 120b of the pattern portion 120 due to the concave shape of the pattern portion 120. Therefore, light (or a portion of the light directed toward the second subpixel SP adjacent thereto by exceeding θc), which is directed toward the adjacent subpixel SP, among the light emitted from the light emitting layer 116 can be blocked by the reflective portion 130 (or the reflective electrode 117) in the first area A1 and/or the second area A2, thereby preventing color mixture with the adjacent subpixels SP from occurring.

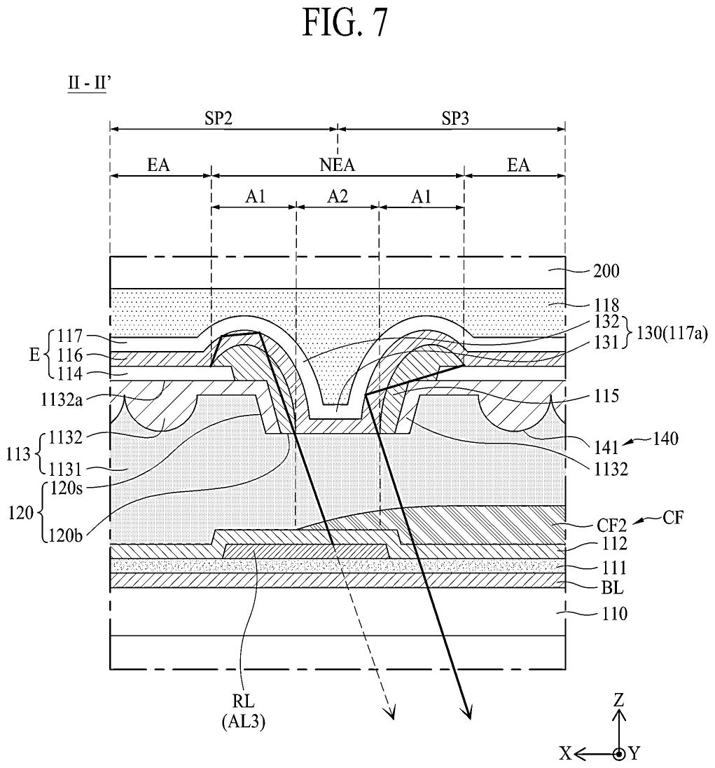

Hereinafter, a relation between the color filter CF and the line 150 in the non-light emission area NEA surrounding each of the first to fourth subpixels SP1 to SP4 will be described with reference to FIGS. 7 to 10.

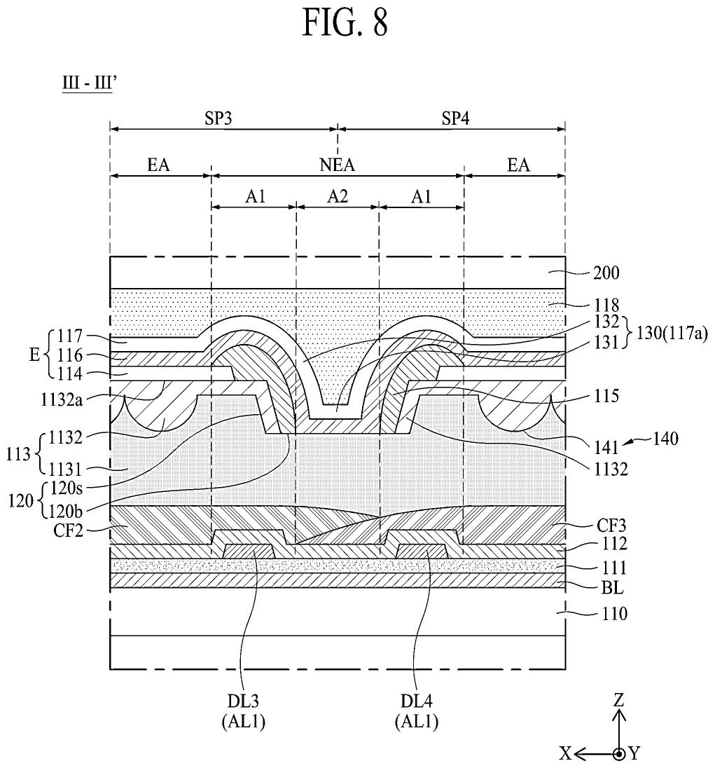

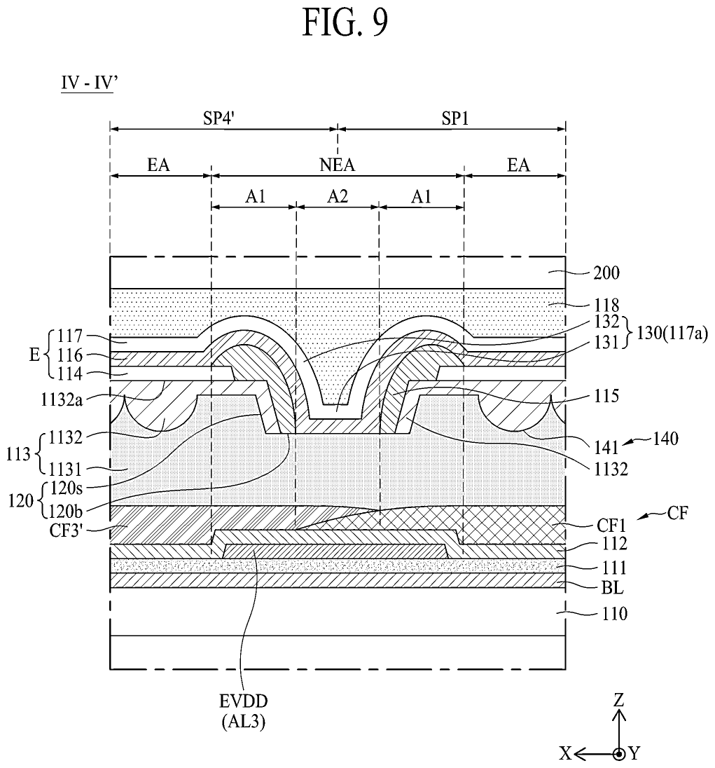

FIG. 7 is a schematic cross-sectional view taken along line II-II′ shown in FIG. 2, FIG. 8 is a schematic cross-sectional view taken along line III-III′ shown in FIG. 2, FIG. 9 is a schematic cross-sectional view taken along line IV-IV′ shown in FIG. 2, and FIG. 10 is a schematic cross-sectional view taken along line V-V′ shown in FIG. 2.

More specifically, FIG. 7 illustrates a structure of the non-light emission area NEA between the second subpixel SP2 and the third subpixel SP3, FIG. 8 illustrates a structure of the non-light emission area NEA between the third subpixel SP3 and the fourth subpixel SP4, FIG. 9 illustrates a structure of a non-light emission area NEA between a first subpixel SP1 and the fourth subpixel SP4′ of the adjacent pixel, and FIG. 10 illustrates a structure of the non-light emission area NEA between the areas including the light emission area EA and the circuit area CA of the first subpixel SP1.

Referring to FIG. 7, the reference line RL can be disposed between the second subpixel SP2 and the third subpixel SP3. The reference line RL according to one example can have a size overlapped with the boundary portion (or the boundary line) between the second subpixel SP2 and the third subpixel SP3. In more detail, the reference line RL can be formed to be extended from the first area A1 of the second subpixel SP2 to the second area A2 adjacent to the first area A1 of the third subpixel SP3. Therefore, the reference line RL can be included in the line AL3 formed over the first area A1 and the second area A2. In this case, the second color filter CF2 can be extended from the light emission area EA of the third subpixel SP3 to the second area A2 adjacent to the first area A1 of the second subpixel SP2 and partially overlap the reference line RL in the second area A2.

Thus, as shown in FIG. 7, the light emitted from the light emission area EA of the second subpixel SP2 and reflected by the reflective portion 130 (or the reflective electrode 117) can be blocked by the second color filter CF2 and the reference line RL, and thus cannot be emitted to the outside. Therefore, color mixture between the second subpixel SP2 and the third subpixel SP3 can be avoided. Further, in this case, the reference line RL may not be the reflective line, unlike the line AL1 disposed in the first area A1. When the reference line RL is the reflective line, the light that has passed through the second color filter CF2 can be reflected on the reference line RL (or an upper surface of the reference line RL) and emitted toward the third subpixel SP3 to generate color mixture. Therefore, in the display apparatus 100 according to one embodiment of the present disclosure, as the second color filter CF2 is disposed to cover the second area A2 by passing through the first area A1 of the third subpixel SP3 and the reference line RL is provided as a non-reflective line that is not reflected, prevention of color mixture of the second subpixel SP2 and the third subpixel SP3 can be maximized, but the present disclosure is not limited thereto. Only a portion of the reference line RL, which is disposed in the first area A1, can be provided as a reflective line.

Meanwhile, the light emitted from the light emission area EA of the third subpixel SP3 and reflected by the reflective portion 130 can be emitted from the first area A1 that is not blocked by the reference line RL. Therefore, light extraction efficiency of the third subpixel SP3 can be improved.

Referring to FIG. 8, the third data line DL3 and the fourth data line DL4 can be disposed between the third subpixel SP3 and the fourth subpixel SP4. Since the third data line DL3 is to drive the third subpixel SP3, the third data line DL3 can be disposed in the first area A1 of the third subpixel SP3. Since the fourth data line DL4 is to drive the fourth subpixel SP4, the fourth data line DL4 can be disposed in the first area A1 of the fourth subpixel SP4. Therefore, the third data line DL3 and the fourth data line DL4 can be included in the line AL1 disposed in the first area A1. In addition, each of the third data line DL3 and the fourth data line DL4 can be provided as the reflective line to reflect light, which is directed toward the reflective line, among the light emitted from the light emission area EA of each subpixel SP, thereby improving light extraction efficiency of each subpixel SP.

Referring back to FIG. 8, the second color filter CF2 and the third color filter CF3 can be formed from the light emission area EA of each subpixel SP to the second area A2 by passing through the first area A1. Therefore, the second color filter CF2 can overlap the third data line DL3 in the first area A1 of the third subpixel SP3, and can overlap the third color filter CF3 in the second area A2. The third color filter CF3 can overlap the fourth data line DL4 in the first area A1 of the fourth subpixel SP4, and can overlap the second color filter CF2 in the second area A2.

In addition, the second color filter CF2 and the third color filter CF3 can overlap each other over the entire second area A2 that overlaps the boundary portion (or the boundary line) between the third subpixel SP3 and the fourth subpixel SP4. As the second color filter CF2 and the third color filter CF3 overlap each other in the entire second area A2 between the third subpixel SP3 and the fourth subpixel SP4, both the light emitted from the third subpixel SP3 and the light emitted from the fourth subpixel SP4 cannot be emitted to the lower surface of the substrate 110 through the second area A2. Therefore, in the display apparatus 100 according to one embodiment of the present disclosure, color filters CF of different colors can be provided to overlap each other in the second area A2 between subpixels SP in which the color filters CF of different colors are provided, whereby color mixture can be prevented from occurring.

Referring to FIG. 9, the pixel power line EVDD can be disposed between the first subpixel SP1 and the fourth subpixel SP4′ of the pixel adjacent to the first subpixel SP1. A pixel power line EVDD according to one example can have a size overlapped with the boundary portion (or the boundary line) between the first subpixel SP1 and the fourth subpixel SP4′ of the pixel adjacent to the first subpixel. In more detail, the pixel power line EVDD can be formed to be extended from the first area A1 of the first subpixel SP1 to the second area A2 adjacent to the first area A1 of the fourth subpixel SP4′. Therefore, the pixel power line EVDD can be included in the line AL3 formed over the first area A1 and the second area A2. In this case, the first color filter CF1 of the first subpixel SP1 can be extended from the light emission area EA of the first subpixel SP1 to the second area A2 adjacent to the first area A1 of the fourth subpixel SP4′ to partially overlap the pixel power line EVDD in the second area A2. The third color filter CF3′ of the fourth subpixel SP4′ of the adjacent pixel can be extended from the light emission area EA of the fourth subpixel SP4′ to the second area A2 adjacent to the first area A1 of the first subpixel SP1 to partially overlap the pixel power line EVDD in the second area A2. Therefore, the first color filter CF1 can overlap a portion of the pixel power line EVDD in the first area A1 of the first subpixel SP1, and can overlap the color filter (or the third color filter CF3′) of the fourth subpixel SP4′ adjacent thereto in the second area A2 and a portion of the pixel power line EVDD. Likewise, the color filter (or the third color filter CF3′) of the fourth subpixel SP4′ can overlap a portion of the pixel power line EVDD in the first area A1 of the fourth subpixel SP4′, and can overlap a portion of the first color filter CF1 of the first subpixel SP1 adjacent thereto in the second area A2 and a portion of the pixel power line EVDD.

Referring to FIG. 9, the color filter (or the third color filter CF3′) of the fourth subpixel SP4′ of the pixel adjacent to the first color filter CF1 of the first subpixel SP1 can overlap the entire second area A2 that overlaps the boundary portion (or the boundary line) between the first subpixel SP1 and the fourth subpixel SP4′. Since the first color filter CF1 and the third color filter CF3′ overlap each other in the entire second area A2 between the first subpixel SP1 and the fourth subpixel SP4′, both the light emitted from the first subpixel SP1 and the light emitted from the fourth subpixel SP4′ cannot be emitted to the lower surface of the substrate 110 through the second area A2. Therefore, in the display apparatus 100 according to one embodiment of the present disclosure, color filters CF of different colors can be provided to overlap each other in the second area A2 between subpixels SP in which the color filters CF of different colors are provided, whereby color mixture can be prevented from occurring.

The light emitted from the light emission area EA of the first subpixel SP1 and reflected by the reflective portion 130 (or the reflective electrode 117) can be blocked by the first color filter CF1 and the reference line RL, and thus cannot be emitted to the outside. The light emitted from the light emission area EA of the fourth subpixel SP4′ and reflected by the reflective portion 130 (or the reflective electrode 117) can be blocked by the third color filter CF3′ and the pixel power line EVDD, and thus cannot be emitted to the outside. Therefore, color mixture between the first subpixel SP1 and the fourth subpixel SP4′ adjacent thereto can be avoided. Further, in this case, the pixel power line EVDD may not be the reflective line, unlike the line AL1 disposed in the first area A1. When the pixel power line EVDD is the reflective line, the light that has passed through the first color filter CF1 can be reflected on the pixel power line EVDD (or an upper surface of the pixel power line EVDD) and emitted toward the fourth subpixel SP4′ to generate color mixture. Similarly, when the pixel power line EVDD is a reflective line, light passing through the third color filter CF3′ is reflected on the pixel power line EVDD (or the upper surface of the pixel power line EVDD) and emitted toward the first subpixel SPIto generate color mixture. Therefore, in the display apparatus 100 according to one embodiment of the present disclosure, as the first color filter CF1 is disposed to cover the second area A2 by passing through the first area A1 of the first subpixel SP1 and the third color filter CF3 is disposed to cover the second area A2 by passing through the first area A1 of the fourth subpixel SP4′, and the pixel power line EVDD is provided as a non-reflective line that is not reflected, prevention of color mixture of the first subpixel SP1 and the fourth subpixel SP4′ adjacent thereto can be maximized.

Meanwhile, the light emitted from the light emission area EA of the first subpixel SP1 and reflected by the reflective portion 130 can be emitted from the first area A1 of the first subpixel SP1, which is not blocked by the pixel power line EVDD, or the light emission area EA of the first subpixel SP1. Further, the light emitted from the light emission area EA of the fourth subpixel SP4′ of the adjacent pixel and reflected by the reflective portion 130 can be emitted from the first area A1 of the fourth subpixel SP4′, which is not blocked by the pixel power line EVDD, or the light emission area EA of the fourth subpixel SP4′. Therefore, light extraction efficiency of each of the first subpixel SP1 and the fourth subpixel SP4′ of the adjacent pixel can be improved.

Referring to FIG. 10, the pixel power line EVDD disposed in the first direction (X-axis direction) can be provided between the areas including the light emission area EA and the circuit area CA of the first subpixel SP1. The pixel power line EVDD disposed in the first direction (X-axis direction) is electrically connected to the pixel power line EVDD disposed in the second direction (Y-axis direction) to apply a pixel power source to the plurality of subpixels SP. The pixel power line EVDD disposed in the first direction (X-axis direction) passes between the light emission area EA and the circuit area CA of each of the subpixels SP and thus can be formed to be thinner than the pixel power line EVDD in the second direction (Y-axis direction), which is disposed outside the pixel P. Therefore, the pixel power line EVDD disposed in the first direction (X-axis direction), passing between the light emission area EA and the circuit area CA can be disposed only in the first area A1 as shown in FIG. 10. Therefore, the pixel power line EVDD disposed in the first area A1 can be provided as the reflective line, thereby improving light extraction efficiency of the first subpixel SP.

The first color filter CF1 of the first subpixel SP1 may not be disposed in the circuit area CA adjacent to the light emission area EA of the first subpixel SP1 in the second direction (Y-axis direction). This is because that when the color filter CF is disposed on the circuit area CA, the thin film transistor can be contaminated by the color filter CF when a contact hole for connecting the pixel electrode 114 with the thin film transistor of the circuit area CA is formed. Therefore, as shown in FIG. 10, the first color filter CF1 of the first subpixel SP1 can be formed so as not to cover the circuit area CA in the second direction (Y-axis direction). For example, the first color filter CF1 can be formed to reach the second area A2 adjacent to the first area A1 of the circuit area CA by passing through the first area A1 adjacent to the light emission area EA in the second direction (Y-axis direction). Therefore, the first color filter CF1 can overlap the pixel power line EVDD disposed in the first direction (X-axis direction), and can be disposed up to the second area A2. As a result, the display apparatus 100 according to one embodiment of the present disclosure can improve light extraction efficiency by the pixel power line EVDD in which the light emitted from the light emission area EA of the first subpixel SP1 is disposed in the first area A1, and can prevent light from being emitted toward the circuit area CA due to the first color filter CF1 formed up to the second area A2 in the second direction (Y-axis direction). Further, in the display apparatus 100 according to one embodiment of the present disclosure, since the color filter CF is not disposed on the circuit area CA, the thin film transistor can be prevented from being contaminated by a material constituting the color filter when the contact hole is formed.

Referring back to FIG. 10, since a predetermined area including the circuit area CA is the non-light emission area NEA, the pixel electrode 114 can be formed only in the portion (the circuit area CA) with which the thin film transistor and the pixel electrode 114 are in contact, and the pixel electrode 114 may not be formed in the other non-light emission area. In addition, since the predetermined area including the circuit area CA is not the light emission area EA, the second layer 1132 of the overcoat layer 113, for example, the plurality of concave portions 141 may not be formed in the predetermined area. The pixel electrode 114 is not formed in the other non-light emission area except the circuit area CA in the non-light emission area including the circuit area CA, and the second layer 1132 of the overcoat layer 113 is not disposed in the entire non-light emission area including the circuit area CA. Therefore, only the bank 115, the light emitting layer 116 and the reflective electrode 117 can be disposed in the other non-light emission areas except the circuit area CA in the predetermined area including the circuit area CA. As a result, the light emission area EA and the circuit area CA of the subpixel SP can be asymmetrically formed based on the second area A2. In this case, as shown in FIGS. 2 and 10, the predetermined area including the circuit area CA can mean the non-light emission area NEA including the circuit area CA of the first subpixel SP1 while being adjacent to the light emission area EA of the first subpixel SP1 in the second direction (Y-axis direction).

Meanwhile, in FIG. 10, the first color filter CF1 of the first subpixel SP1 can be formed to be extended to the second area A2 adjacent to the first area A1 of the circuit area CA, and thus can be formed in accordance with the equation expressed in the description related to FIG. 6.

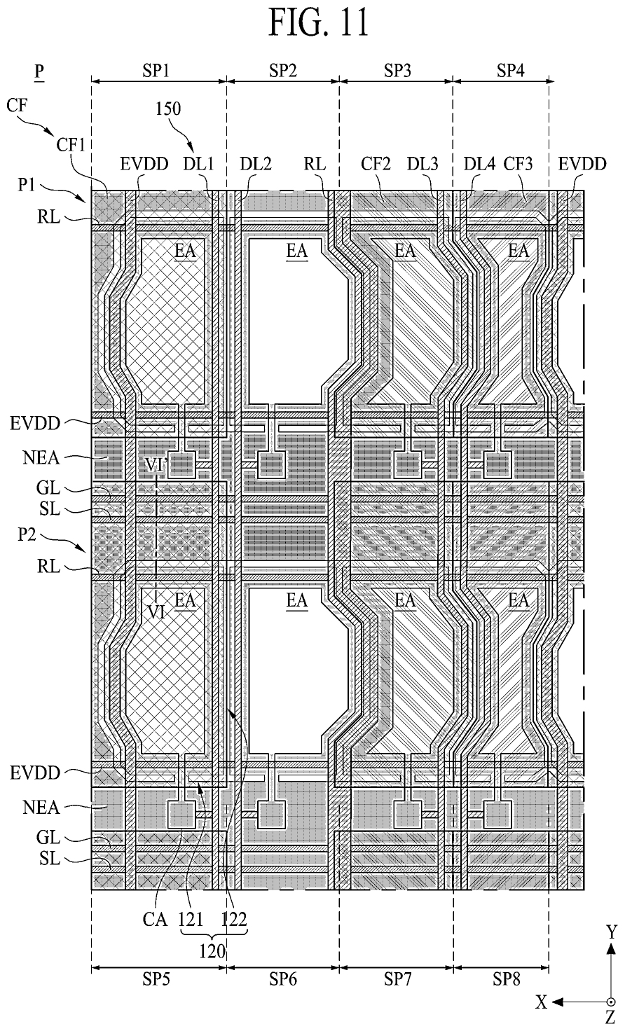

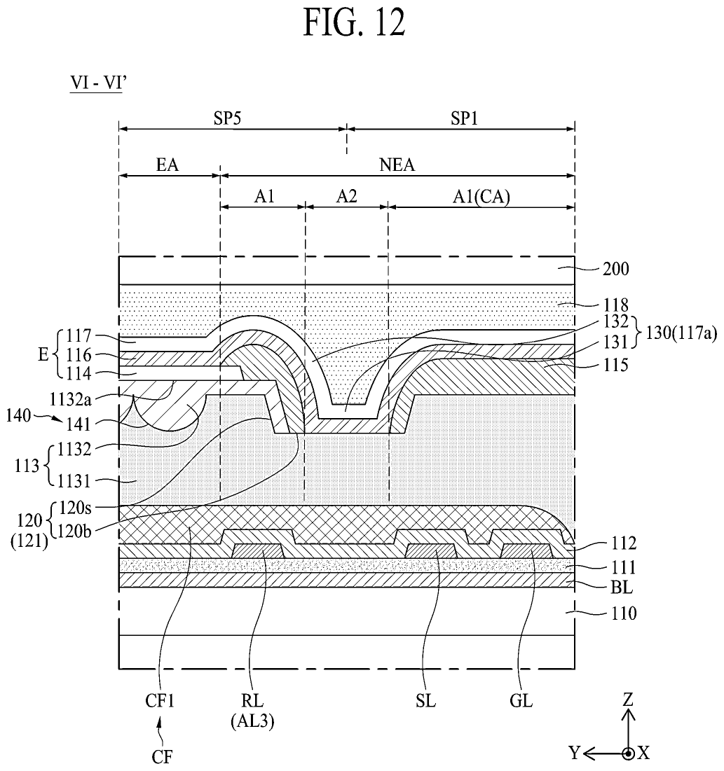

FIG. 11 is a schematic plan view illustrating a plurality of pixels of a display apparatus according to one embodiment of the present disclosure, and FIG. 12 is a schematic cross-sectional view taken along line VI-VI′ shown in FIG. 11.

Referring to FIGS. 11 and 12, the plurality of pixels P can include a first pixel P1 and a second pixel P2 adjacent to the first pixel P1 in the second direction (Y-axis direction). The second pixel P2 can include a plurality of subpixels SP. The second pixel P2 according to one example can include a fifth subpixel SP5 adjacent to the first subpixel SP1 of the first pixel P1 and emitting red light. The second pixel P2 according to one example can include a sixth subpixel SP6 adjacent to the second subpixel SP2 of the first pixel P1 and emitting white light. The second pixel P2 according to one example can include a seventh subpixel SP7 adjacent to the third subpixel SP3 of the first pixel P1 and emitting blue light. The second pixel P2 according to one example can include an eighth subpixel SP8 adjacent to the fourth subpixel SP4 of the first pixel P1 and emitting green light.

Since the fifth subpixel SP5 emits the same red light as that of the first subpixel SP1, the fifth subpixel SP5 can include a first color filter CF1 that is a red color filter. Therefore, the display apparatus 100 according to one embodiment of the present disclosure can be provided in a stripe shape in which light of the same color is emitted in the second direction (Y-axis direction).

Referring to FIG. 11, the first subpixel SP1 can include the circuit area CA in the non-light emission area NEA. A gate line GL and a sensing line SL can be disposed in the first direction (X-axis direction) between the circuit area CA of the first subpixel SP1 and the light emission area EA of the fifth subpixel SP5.

Referring to FIG. 11, the first color filter CF1 may not cover the circuit area CA of each of the first subpixel SP1 and the fifth subpixel SP5. The second color filter CF2 may not cover the circuit area CA of each of the third subpixel SP3 and the seventh subpixel SP7. The third color filter CF3 may not cover the circuit area CA of each of the fourth subpixel SP4 and the eighth subpixel SP8. This is because, as described above, when the color filter CF is disposed on the circuit area CA, the thin film transistor can be contaminated by the color filter CF when the contact hole for connecting the pixel electrode 114 with the thin film transistor of the circuit area CA is formed. Therefore, as shown in FIG. 11, the color filter CF can be formed so as not to cover the circuit area CA of each of the plurality of subpixels SP and the periphery of the circuit area CA.

In the display apparatus 100 according to one embodiment of the present disclosure, the color filter CF can be provided to cover the other area except the circuit area CA and the periphery of the circuit area CA in the subpixels except the second subpixel SP2 and the sixth subpixel SP6, which are white subpixels. Therefore, the display apparatus 100 according to one embodiment of the present disclosure can maintain a color and a color viewing angle of the light emission area (or emission area) of the light reflected by the reflective portion 130. In this case, the color viewing angle can mean that color coordinates are shifted in a direction in which the color gamut is reduced.

Referring to FIG. 12, since the color filter is not disposed in the circuit area CA of the first subpixel SP1, the first color filter CF1 of the fifth subpixel SP5 can overlap the gate line GL and the sensing line SL, which are disposed in the first area A1 of the first subpixel SP1, and may not overlap the circuit area CA of the first subpixel SP1. The circuit area CA of the first subpixel SP1 can mean an area in which the pixel electrode 114 of the first subpixel SP1 is in contact with the thin film transistor of the first subpixel SP1 through the contact hole. Therefore, since the thin film transistor of the first subpixel SP1 is not shown in FIG. 12, the first color filter CF1 of the fifth subpixel SP5 can be formed only up to an area that does not overlap the thin film transistor of the first subpixel SP1.

As shown in FIG. 12, the first color filter CF1 of the fifth subpixel SP5 can be provided to cover the reference line RL disposed in the first area A1 of the fifth subpixel SP5 and the sensing line SL and the gate line GL, which are disposed in the first area A1 of the first subpixel SP1. Therefore, in a repair process of cutting the sensing line SL and/or the gate line GL using a laser to make only a defective subpixel in an impossible operation state, the first color filter CF1 can block the laser from reaching the reflective electrode 117. Therefore, in the display apparatus 100 according to one embodiment of the present disclosure, since the first color filter CF1 of the fifth subpixel SP5 is provided to overlap the sensing line SL and the gate line GL of the first subpixel SP1, the reflective electrode 117 can be protected from the laser used for the repair process, whereby lifespan of the reflective electrode 117 may not be degraded.

Meanwhile, as shown in FIG. 12, the plurality of concave portions 141 and the pixel electrode 114 for improving light extraction may not be disposed in the non-light emission area NEA in which the sensing line SL and the gate line GL of the first subpixel SP1 are disposed. Therefore, only the bank 115, the light emitting layer 116 and the reflective electrode 117 can be disposed in the non-light emission area NEA in which the sensing line SL and the gate line GL of the first subpixel SP1 are disposed. Therefore, the first area A1 of the fifth subpixel SP5 and the first area A1 of the first subpixel SP1 can be formed in the second direction (Y-axis direction) asymmetrically based on the second area A2.

As a result, the display apparatus according to one or more embodiments of the present disclosure can obtain the following effects.

First, in the display apparatus 100 according to the present disclosure, the reflective portion 130 is provided on the pattern portion 120 in the periphery of the non-light emission area NEA between the plurality of subpixels SP so that the reflective light can be extracted even from the non-light emission area NEA, whereby overall light efficiency can be improved.

Second, in the display apparatus 100 according to the present disclosure, light can be extracted even from the non-light emission area NEA due to the reflective portion 130 provided on the pattern portion 120 of the non-light emission area NEA, so that the display apparatus 100 according to the present disclosure can have the same light emission efficiency or more improved light emission efficiency even with low power as compared with the display apparatus having no reflective portion, whereby overall power consumption can be reduced.

Third, the display apparatus 100 according to one embodiment of the present disclosure can allow the light emitting element layer E to emit light even with low power, thereby improving lifespan of the light emitting element layer E.

Fourth, in the display apparatus 100 according to the present disclosure, as each of the plurality of subpixels SP includes the light extraction portion 140 that includes the plurality of concave portions 141, a path of the light, which is directed toward the adjacent subpixel SP, among the light emitted from the light emitting element layer can be changed so that the light can be extracted through the reflective portion 130, whereby the luminance retention rate and light extraction efficiency can be more improved.

Fifth, in the display apparatus 100 according to one embodiment of the present disclosure, since at least one of the plurality of lines 150 disposed in the non-light emission area NEA of each of the plurality of subpixels SP can be provided to partially overlap the pattern portion 120, the light, which is directed toward the line 150, among the light emitted from the light emitting element layer can be extracted through the line 150 and the reflective portion 130, whereby light extraction efficiency can be maximized.

Sixth, in the display apparatus 100 according to one embodiment of the present disclosure, the light emitted from each subpixel SP can be prevented from being emitted to the adjacent subpixel SP due to the color filters overlapped with each other at the boundary portion of the subpixels SP, whereby color mixture between the subpixels SP can be prevented from occurring.

Seventh, in the display apparatus 100 according to one embodiment of the present disclosure, since the reflective portion 130 is disposed on the pattern portion 120 between the subpixels SP for emitting light of different colors, light of different colors can be more effectively prevented from being emitted to other adjacent subpixels SP. Therefore, the display apparatus 100 according to the present disclosure can prevent color mixture (or color distortion) between the subpixels SP for emitting light of different colors, thereby improving color purity.

Eighth, in the display apparatus 100 according to one embodiment of the present disclosure, since the color filter CF of each subpixel SP is provided to overlap the sensing line SL and the gate line GL between the subpixels SP in the second direction (Y-axis direction), the reflective electrode 117 can be protected from the laser used for the repair process, whereby deterioration of lifespan of the light emitting layer 116 due to the damage of the reflective electrode 117 can be avoided.

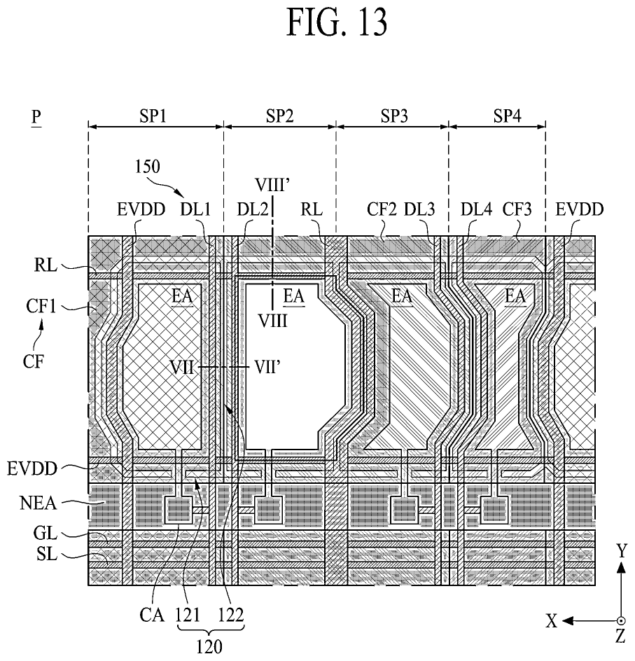

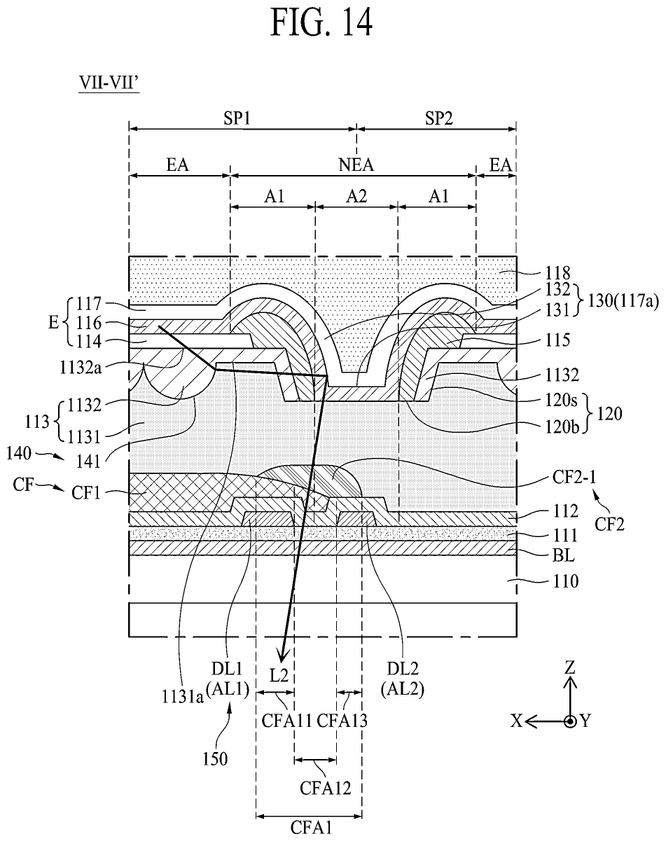

FIG. 13 is a schematic plan view illustrating a display apparatus according to another embodiment of the present disclosure, and FIG. 14 is a schematic cross-sectional view taken along line VII-VII′ shown in FIG. 13.

Referring to FIGS. 13 and 14, the display apparatus 100 according to another embodiment of the present disclosure is the same as the display apparatus of FIG. 1 except that the structure of the second color filter CF2 is changed. Therefore, the same reference numerals will be given to the same elements as those of FIG. 1, and the elements different from those of FIG. 1 will be described below.

In case of the display apparatus according to FIG. 1 described above, the second color filter CF2 which is a blue color filter is disposed in the third subpixel SP3 that is a blue subpixel. Therefore, in case of the display apparatus according to FIG. 1, only the first color filter CF1 that is a red color filter is partially disposed between the first subpixel SP1 which are red subpixel and the second subpixel SP2. Therefore, in the display apparatus according to FIG. 1, light leakage or color mixture may occur between the first subpixel SP1 and the second subpixel SP2 when the first subpixel SP1 or the second subpixel SP2 emits light.

On the contrary, in the display apparatus according to FIG. 13, the second color filter CF2 may include an extended color filter CF2-1 extended from the third subpixel SP3 to the second subpixel SP2 and disposed to surround the second subpixel SP2 (or the light emission area EA of the second subpixel SP2). The extended color filter CF2-1 according to one example may be a portion where the second color filter CF2 in the third subpixel SP3 is extended. The extended color filter CF2-1 may be formed integrally with or separately from the second color filter CF2 in the third subpixel SP3. The second color filter CF2 and the extended color filter CF2-1 according to one example may be blue color filters. Therefore, in case of the display apparatus according to FIG. 13, since the extended color filter CF2-1 partially overlaps the first color filter CF1 in the non-light emission area NEA between the first subpixel SP1 and the second subpixel SP2, occurrence of light leakage or color mixture between the first subpixel SP1 and the second subpixel SP2 may be avoided when the first subpixel SP2 or the second subpixel SP2 emits light.

Also, in the display apparatus according to FIG. 13, the extended color filter CF2-1 of the second color filter CF2 is disposed to surround the edge of the second subpixel SP2, so that light leakage corresponding to blue may occur above and/or below the second subpixel SP2, which is a white subpixel, whereby a color temperature (or correlated color temperature, CCT) may be improved.

In general, chromaticity of a light source or reference white may be expressed as a temperature of the closest area on a radiation curve instead of coordinates on a two-dimensional chromaticity chart. The color temperature is used as a numerical value to indicate the degree to which a white color is expressed to be close. When a color expressed in the display apparatus is close to blue, the color temperature is indicated to be high, and when it is close to yellow, the color temperature is indicated to be low. As the color temperature is high, a color of higher quality is expressed. In particular, in order for a display apparatus for displaying an image by using a light emitting layer for emitting white light to express a color of high quality, it is preferable that the color temperature of white is high.

Therefore, in the display apparatus 100 according to another embodiment of the present disclosure, the extended color filter CF2-1 of the second color filter CF2 is disposed to surround the edge (the light emission area EA of the second subpixel SP2) of the second subpixel SP2, so that light leakage corresponding to blue may occur at the edge of the second subpixel SP2, whereby the color temperature may be improved. As a result, in the display apparatus 100 according to another embodiment of the present disclosure, the color of high quality may be expressed.

Meanwhile, in case of the general display apparatus, when the second subpixel (or the white subpixel) is driven, the third subpixel (or the blue subpixel) is also driven to compensate for the decrease in color temperature. However, since element efficiency of the blue subpixel is lower than that of other red and green subpixels, power consumption of the blue subpixel is increased. Therefore, in case of the general display apparatus, a problem occurs in that lifespan of the light emitting layer of the blue subpixel in which power consumption is increased is shortened. However, in the display apparatus 100 according to another embodiment of the present disclosure, since the color temperature may be improved due to the extended color filter CF2-1 even though the white subpixel SP2 is only driven, the blue subpixel SP3 is not driven or power consumption of the blue subpixel SP3 is lowered so that driving stress may be reduced, whereby the overall lifespan may be improved.

Referring back to FIG. 13, the extended color filter CF2-1 may be disposed so as not to overlap the light emission area EA of the second subpixel SP2. For example, the extended color filter CF2-1 may be partially disposed in the non-light emission area NEA surrounding the light emission area EA of the second subpixel SP2. Therefore, when the white subpixel SP2 emits light, since the extended color filter CF2-1 does not interfere with white light emitted from the light emission area EA of the white subpixel SP2, deterioration in light efficiency of white light may be avoided.

Referring to FIG. 14, in the display apparatus 100 according to another embodiment of the present disclosure, the first data line DL1 may be disposed in the first area A1 of the first subpixel SP1, and the second data line DL2 may be disposed in the second area A2 between the first area A1 of the first subpixel SP1 and the first area A1 of the second subpixel SP2. In this case, the extended color filter CF2-1 may partially overlap the first data line DL1. Also, the extended color filter CF2-1 may partially overlap the second data line DL2. For example, based on FIG. 14, the extended color filter CF2-1 may overlap the remaining portion (or right portion) except a portion of a left side of the first data line DL1. Also, based on FIG. 14, the extended color filter CF2-1 may overlap the remaining portion (or left portion) except a portion of a right side of the second data line DL2. Also, the extended color filter CF2-1 may overlap an area between the remaining portion (or right portion) of the first data line DL1 and the remaining portion (or left portion) of the second data line DL2. Therefore, some of the light emitted from the light emitting layer 116 of the first subpixel SP1 may be reflected by the reflecting portion 130 and then emitted to the outside in the form of the reflective light L2 through the area between the remaining portion (or right portion) of the first data line DL1 and the remaining portion (or left portion) of the second data line DL2.

The display apparatus 100 according to another embodiment of the present disclosure may include a first color filter area CFA1. The first color filter area CFA1 according to one example may be an area in which the extended color filter CF2-1 is disposed in the non-light emission area NEA between the first subpixel SP1 and the second subpixel SP2.

Referring to FIG. 14, the first color filter area CFA1 may include a first side sub-color filter area CFA11, a second side sub-color filter area CFA12, and a third side sub-color filter area CFA13.

The first side sub-color filter area CFA11 may be an area in which the extended color filter CF2-1 and the first data line DL1 and the first color filter CF1 overlap one another other in the third direction (Z-axis direction). The second side sub-color filter area CFA12 may be an area in which the extended color filter CF2-1 and the first color filter CF1 overlap each other in the third direction (Z-axis direction). The third side sub-color filter area CFA13 may be an area in which the extended color filter CF2-1 and the second data line DL2 overlap each other in the third direction (Z-axis direction).

As shown in FIG. 14, some of the light emitted from the light emitting layer 116 of the first subpixel SP1 may be refracted by the concave portion 141 and reflected by the reflective portion 130 and then emitted to the outside through the second side sub-color filter area CFA12. Since the second side sub-color filter area CFA12 is an area in which the extended color filter CF2-1 that is a blue color filter and the first color filter CF1 that is a red color filter overlap each other, the light emitted to the outside may have a blackish color.

As a result, the display apparatus 100 according to another embodiment of the present disclosure may be provided to block a color mixable area by overlap between the extended color filter CF2-1 and the first color filter CF1 when the first subpixel SP1 or the second subpixel SP2 is turned on due to a defect (or process dispersion change, etc.).

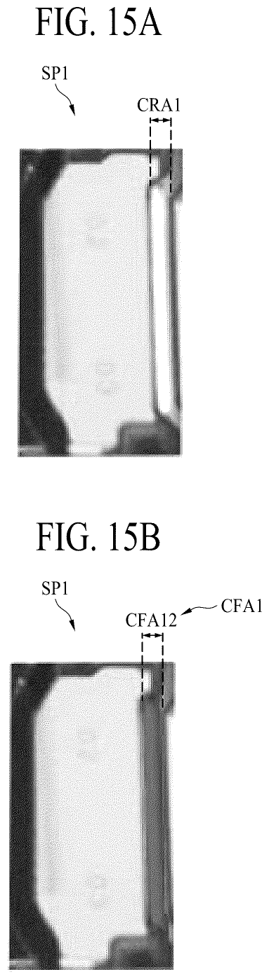

FIG. 15A is an image illustrating light extraction characteristics of a red subpixel of a display apparatus according to a comparative example, and FIG. 15B is an image illustrating light extraction characteristics of a red subpixel of a display apparatus according to another embodiment of the present disclosure.

FIG. 15A is an image illustrating light extraction characteristics of the red subpixel when only the red color filter is disposed between the red subpixel and the white subpixel of the display apparatus according to the comparative example, and FIG. 15B is an image illustrating light extraction characteristics of the red subpixel when the red color filter CF1 and the extended color filter CF2-1 are disposed to overlap each other between the red subpixel (or the first subpixel SP1) and the white subpixel (or the second subpixel SP2) of the display apparatus 100 according to another embodiment of the present disclosure.

In the display apparatus according to the comparative example, since only the red color filter is disposed between the red subpixel and the white subpixel as shown in the image of FIG. 15A, red and/or white light leakage occurs in the first corresponding area CRA1 corresponding to the second side sub-color filter area CFA12 of the display apparatus 100 according to another embodiment of the present disclosure. Therefore, as shown in FIG. 15A, in the display apparatus according to the comparative example, light having a reddish color may be emitted from the first corresponding area CRA1 when the red subpixel emits light. On the other hand, in the display apparatus 100 according to another embodiment of the present disclosure, as shown in the image of FIG. 15B, since the red color filter CF1 and the extended color filter CF2-1 are disposed to overlap each other in the second side sub-color filter area CFA12, light having a blackish color may be emitted from the second side sub-color filter area CFA12.

As a result, in the display apparatus 100 according to another embodiment of the present disclosure, since light having a reddish color may be prevented from being emitted from the second side sub-color filter area CFA12, the color temperature may be improved as compared with the display apparatus according to the comparative example.

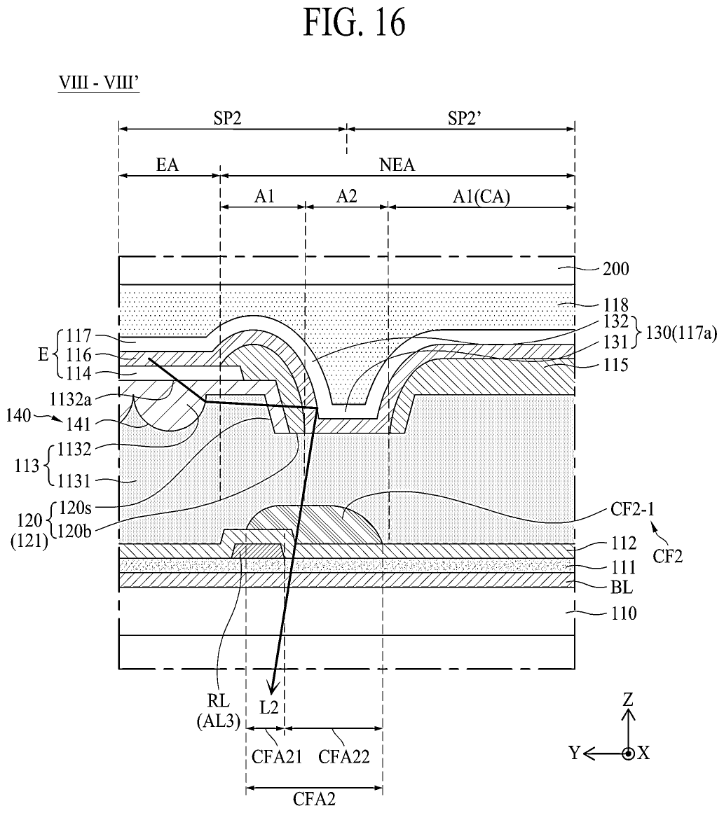

FIG. 16 is schematic cross-sectional view taken along line VIII-VIII′ shown in FIG. 13.

Referring to FIG. 13, the reference line RL may be disposed to be spaced apart from an upper side of the light emission area EA of the second subpixel SP2. In detail, referring to FIG. 16, the reference line RL may be disposed in the first area A1 of the second subpixel SP2. In this case, the extended color filter CF2-1 may partially overlap the reference line RL.

For example, based on FIG. 16, the extended color filter CF2-1 may overlap the remaining portion (or right portion) except a portion of a left side of the reference line RL. Also, based on FIG. 16, the extended color filter CF2-1 may partially overlap an area (e.g., a portion of the first area A1 and a portion of the second area A2) in which the reference line RL is not disposed. Therefore, some of the light emitted from the light emitting layer 116 of the second subpixel SP2 may be reflected by the reflective portion 130 and then emitted to the outside in the form of the reflective light L2 through the area (e.g., a portion of the first area A1 and a portion of the second area A2) in which the reference line RL is not disposed.

The display apparatus 100 according to another embodiment of the present disclosure may include a second color filter area CFA2. The second color filter area CFA2 according to one example may be an area in which the extended color filter CF2-1 is disposed in the non-light emission area NEA between the second subpixel SP2 and another second subpixel SP2′ which is disposed to be adjacent to the second subpixel SP2 in the second direction (Y-axis direction).

Referring to FIG. 16, the second color filter area CFA2 may include a first upper sub-color filter area CFA21 and a second upper sub-color filter area CFA22.

The first upper sub-color filter area CFA21 may be an area in which the extended color filter CF2-1 and the reference line RL overlap each other in the third direction (Z-axis direction). The second upper sub-color filter area CFA22 may be an area disposed to be adjacent to the first upper sub-color filter area CFA21. The extended color filter CF2-1 may be disposed in the second upper sub-color filter area CFA22.

As shown in FIG. 16, some of the light emitted from the light emitting layer 116 of the second subpixel SP2 may be refracted by the concave portion 141, reflected by the reflective portion 130 and then emitted to the outside through the second upper sub-color filter area CFA22. Since the second upper sub-color filter area CFA22 is an area in which the extended color filter CF2-1 that is a blue color filter is disposed, the light emitted to the outside may have a blueish color due to color conversion.

As a result, in the display apparatus 100 according to another embodiment of the present disclosure, the color temperature may be improved when the second subpixel SP2 is driven (or turned on), whereby driving stress of the blue subpixel (or the third subpixel SP3) may be reduced.

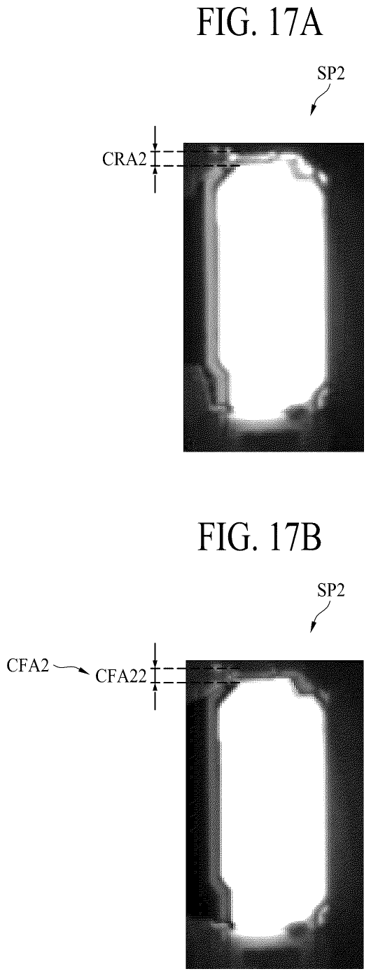

FIG. 17A is an image illustrating light extraction characteristics of a white subpixel of a display apparatus according to a comparative example, and FIG. 17B is an image illustrating light extraction characteristics of a white subpixel of a display apparatus according to another embodiment of the present disclosure.

FIG. 17A is an image illustrating light extraction characteristics of the white subpixel when the color filter (or blue color filter) is not disposed above the white subpixel of the display apparatus according to the comparative example, and FIG. 17B is an image illustrating light extraction characteristics of the white subpixel when the blue color filter (or extended color filter CF2-1) is disposed above the white subpixel (or the second subpixel SP2) of the display apparatus 100 according to another embodiment of the present disclosure.

In the display apparatus according to the comparative example, since the color filter (or blue color filter) is not disposed above the white subpixel as shown in the image of FIG. 17A, white light leakage occurs in the second corresponding area CRA2 corresponding to the second upper sub-color filter area CFA22 of the display apparatus 100 according to another embodiment of the present disclosure. Therefore, as shown in FIG. 17A, in the display apparatus according to the comparative example, light having a whitish color may be emitted from the second corresponding area CRA2 when the white subpixel emits light. On the other hand, in the display apparatus 100 according to another embodiment of the present disclosure, as shown in the image of FIG. 17B, since the extended color filter CF2-1 is disposed in the second upper sub-color filter area CFA22, light having a blueish color may be emitted from the second upper sub-color filter area CFA22.

As a result, in the display apparatus 100 according to another embodiment of the present disclosure, since the light having a blueish color may be emitted from the second upper sub-color filter area CFA22, the color temperature may be improved as compared with the display apparatus according to the comparative example.

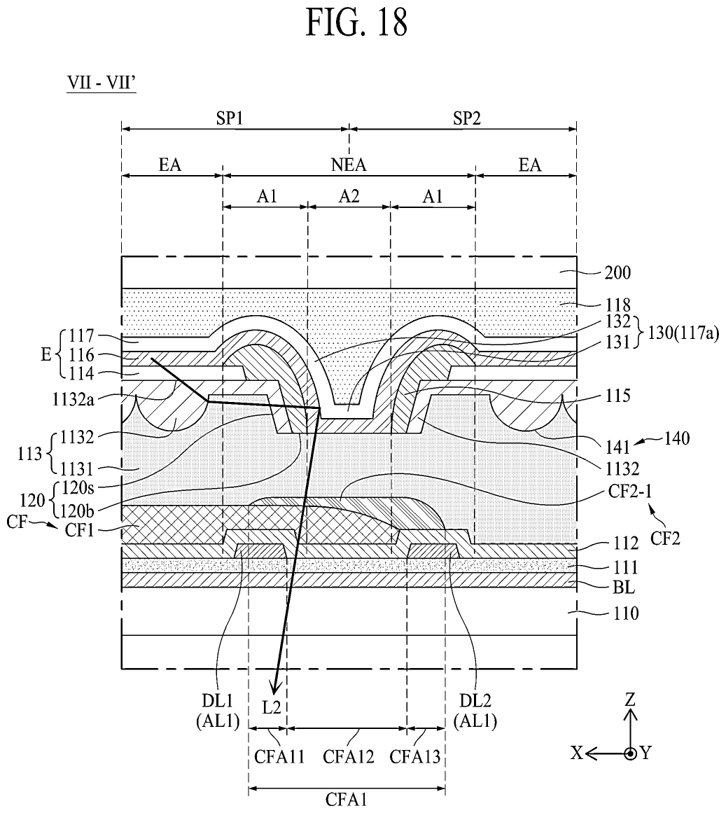

FIG. 18 is schematic cross-sectional view illustrating another example of FIG. 14.

The display apparatus 100 according to FIG. 18 is the same as the display apparatus of FIG. 14 except that the arrangement position of the second data line DL2 and the structure of the extended color filter CF2-1 are changed. Therefore, the same reference numerals will be given to the same elements as those of FIG. 14, and the elements different from those of FIG. 14 will be described below.

In case of the display apparatus according to FIG. 14 described above, the first data line DL1 is disposed in the first area A1 of the first subpixel SP1, and the second data line DL2 is disposed in the second area A2 between the first area A1 of the first subpixel SP1 and the first area A1 of the second subpixel SP2. In addition, the extended color filter CF2-1 partially overlaps the first color filter CF1 and the first data line DL1, and partially overlaps the second data line DL2.

Therefore, in case of the display apparatus according to FIG. 14, the light emitted from the first subpixel SP1 may be emitted to the outside through the second side sub-color filter area CFA12 between the first data line DL1 and the second data line DL2. Since the second side sub-color filter area CFA12 is an area in which the extended color filter CF2-1 that is a blue color filter and the first color filter CF1 that is a red color filter overlap each other, the light emitted to the outside may have a blackish color.

On the contrary, in case of the display apparatus of FIG. 18, the first data line DL1 may be disposed in the first area A1 of the first subpixel SP1, and the second data line DL2 may be disposed in the first area A1 of the second subpixel SP2. In this case, the extended color filter CF2-1 may partially overlap the first data line DL1. Also, the extended color filter CF2-1 may partially overlap the second data line DL2. For example, based on FIG. 18, the extended color filter CF2-1 may overlap the remaining portion (or right portion) except a portion of the left side of the first data line DL1. Also, based on FIG. 18, the extended color filter CF2-1 may overlap the remaining portion (or left portion) except a portion of the right side of the second data line DL2. Also, the extended color filter CF2-1 may overlap the area between the remaining portion (or right portion) of the first data line DL1 and the remaining portion (or left portion) of the second data line DL2. Therefore, some of the light emitted from the light emitting layer 116 of the first subpixel SP1 may be reflected by the reflective portion 130 and then emitted to the outside in the form of the reflective light L2 through the area between the remaining portion (or right portion) of the first data line DL1 and the remaining portion (or left portion) of the second data line DL2.

Another example of the display apparatus 100 according to another embodiment of the present disclosure of FIG. 18 may include a first color filter area CFA1. The first color filter area CFA1 according to one example may be an area in which the extended color filter CF2-1 is disposed in the non-light emission area NEA between the first subpixel SP1 and the second subpixel SP2.

Referring to FIG. 18, the first color filter area CFA1 may include a first side sub-color filter area CFA11, a second side sub-color filter area CFA12, and a third side sub-color filter area CFA13.

The first side sub-color filter area CFA11 may be an area in which the extended color filter CF2-1 and the first data line DL1 and the first color filter CF1 overlap one another in the third direction (Z-axis direction). The second side sub-color filter area CFA12 may be an area in which the extended color filter CF2-1 and the first color filter CF1 overlap each other in the third direction (Z-axis direction). The third side sub-color filter area CFA13 may be an area in which the extended color filter CF2-1 and the second data line DL2 overlap each other in the third direction (Z-axis direction).

As shown in FIG. 18, some of the light emitted from the light emitting layer 116 of the first subpixel SP1 may be refracted by the concave portion 141, reflected by the reflective portion 130 and then emitted to the outside through the second side sub-color filter area CFA12. Since the second side sub-color filter area CFA12 is an area in which the extended color filter CF2-1 that is a blue color filter and the first color filter CF1 that is a red color filter overlap each other, the light emitted to the outside may have a blackish color.

As a result, in another example of the display apparatus 100 according to another embodiment of the present disclosure, the second side sub-color filter area CFA12 may be wider than that of the display apparatus according to FIG. 14. Therefore, in another example of the display apparatus 100 according to another embodiment of the present disclosure, when the first sub-pixel SP1 or the second sub-pixel SP2 is turned on, an area for blocking a color mixable area may be provided to be wider, whereby prevention of color mixture may be maximized.

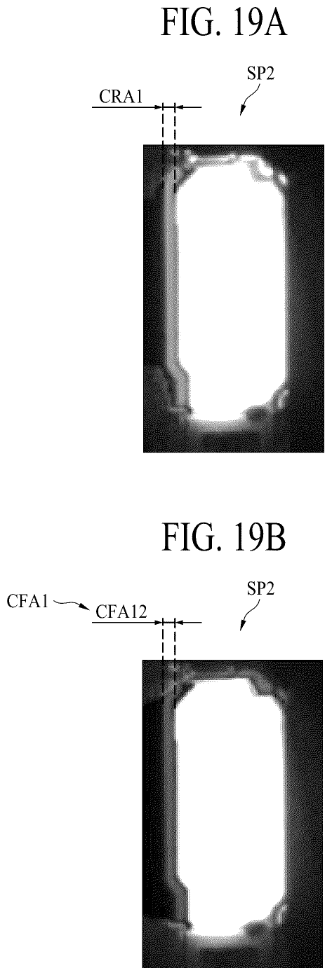

FIG. 19A is an image illustrating light extraction characteristics of another white subpixel of a display apparatus according to a comparative example, and FIG. 19B is an image illustrating light extraction characteristics of another white subpixel of a display apparatus according to another embodiment of the present disclosure.

FIG. 19A is an image illustrating light extraction characteristics of the white subpixel when only the red color filter is disposed between the red subpixel and the white subpixel in accordance with another example of the display apparatus according to the comparative example, and FIG. 19B is an image illustrating light extraction characteristics of the red subpixel when the red color filter CF1 and the extended color filter CF2-1 are disposed to overlap each other between the red subpixel (or the first subpixel SP1) and the white subpixel (or the second subpixel SP2) in accordance with another example of the display apparatus 100 according to another embodiment of the present disclosure.

In another example of the display apparatus according to the comparative example, as shown in the image of FIG. 19A, since only the red color filter is disposed between the red subpixel and the white subpixel, red and/or white light leakage occurs in the first corresponding area CRA1 corresponding to the second side sub-color filter area CFA12 of another example of the display apparatus 100 according to another embodiment of the present disclosure. Therefore, in another example of the display apparatus according to the comparative example, as shown in FIG. 19A, light having a reddish color may be emitted from the first corresponding area CRA1 when the red subpixel emits light. On the other hand, in another example of the display apparatus 100 according to another embodiment of the present disclosure, as shown in the image of FIG. 19B, since the red color filter CF1 and the extended color filter CF2-1 are disposed to overlap each other in the second side sub-color filter area CFA12, light having a blackish color may be emitted from the second side sub-color filter area CFA12.

As a result, in another example of the display apparatus 100 according to another embodiment of the present disclosure, since the light having a reddish color may be prevented from being emitted from the second side sub-color filter area CFA12, the color temperature may be improved as compared with another example of the display apparatus according to the comparative example.

According to the present disclosure, the following advantageous effects can be obtained.

In the display apparatus according to the present disclosure, the reflective portion is provided in the periphery of the non-light emission area, so that the light can be extracted even from the non-light emission area, whereby overall light efficiency can be improved.

In the display apparatus according to the present disclosure, since the light can be extracted even from the non-light emission area, the display apparatus according to the present disclosure can have the same light emission efficiency or more improved light emission efficiency even with low power as compared with the display apparatus having no reflective portion, whereby overall power consumption can be reduced.

In the display apparatus according to the present disclosure, each of the plurality of subpixels includes the light extraction portion that includes the plurality of concave portions, so that the luminance retention rate and light extraction efficiency of the light emitted from the light emitting element layer can be more improved.

In the display apparatus according to the present disclosure, since the reflective portion is disposed in the non-light emission area adjacent to the corner portion of the light emission area, the light can be extracted even from the non-light emission area adjacent to the corner portion of the light emission area, whereby light emission efficiency can be increased.

In the display apparatus according to the present disclosure, since the reflective line is disposed in the non-light emission area, light extraction efficiency of the light emitted from the light emitting element layer can be maximized.

In the display apparatus according to the present disclosure, since the reflective line is provided in the non-light emission area, color mixture between the subpixels can be prevented from occurring.

In the display apparatus according to one embodiment of the present disclosure, since the color filter can be provided to cover the circuit area and the other area except the periphery of the circuit area in the subpixels except the white subpixel, the color and the color viewing angle of the light emission area (or the emission area) reflected by the reflective portion can be maintained.

In the display apparatus according to another embodiment of the present disclosure, the blue color filter of the blue subpixel may be provided to surround the edge of the white subpixel, so that the color temperature of the white subpixel may be improved.

In the display apparatus according to another embodiment of the present disclosure, since driving stress of the blue subpixel may be relatively reduced due to improvement of the color temperature of the white subpixel, overall usage lifespan may be improved.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims, and it is intended that all variations or modifications derived from the meaning, scope and equivalent concept of the claims fall within the scope of the present disclosure.

What is claimed is:

1. A display apparatus comprising:
a substrate including a plurality of pixels having a plurality of subpixels;
a pattern portion on the substrate and formed to be concave between the plurality of subpixels;
a reflective portion on the pattern portion; and
a plurality of lines configured to drive the plurality of subpixels,
wherein the plurality of subpixels include a light emission area and a non-light emission area adjacent to the light emission area,
the plurality of lines are disposed in the non-light emission area,
the pattern portion surrounds the light emission area, and
at least one of the plurality of lines partially overlaps the pattern portion.

2. The display apparatus of claim 1, wherein the non-light emission area includes a first area adjacent to the light emission area and a second area adjacent to the first area and spaced apart from the light emission area, and
the plurality of lines are disposed in at least one of the first area and the second area of the non-light emission area.

3. The display apparatus of claim 2, wherein the second area overlaps a boundary portion between the plurality of subpixels.

4. The display apparatus of claim 2, wherein each of the plurality of subpixels includes a bank disposed in the non-light emission area, and
the banks of the plurality of subpixels are disposed in the first area and are spaced apart from each other based on the second area.

5. The display apparatus of claim 2, wherein the reflective portion includes a flat surface disposed in the second area, and a curved surface connected to the flat surface.

6. The display apparatus of claim 2, further comprising a color filter between the plurality of lines and the pattern portion,
wherein the color filter extends from the light emission area of the plurality of subpixels to the second area and partially overlaps at least one of the plurality of lines disposed in the at least one of the first area and the second area.

7. The display apparatus of claim 2, wherein the plurality of subpixels include:
a first subpixel configured to emit red light;
a second subpixel adjacent to the first subpixel, and configured to emit white light;
a third subpixel adjacent to the second subpixel, and configured to emit blue light; and
a fourth subpixel adjacent to the third subpixel, and configured to emit green light,
the plurality of lines include a first data line configured to drive the first subpixel and a second data line spaced apart from the first data line and configured to drive the second subpixel,
the first data line is disposed in the first area, and
the second data line is disposed in the second area.

8. The display apparatus of claim 7, further comprising:
a first color filter provided in the first subpixel;
a second color filter disposed in the third subpixel;
a third color filter disposed in the fourth subpixel; and
a reference line overlapped between the second subpixel and the third subpixel,
wherein the reference line extends from the first area of the second subpixel to the second area adjacent to the first area of the third subpixel, and
the second color filter extends from the light emission area of the third subpixel to the second area adjacent to the first area of the second subpixel and partially overlaps the reference line.

9. The display apparatus of claim 8, wherein the plurality of lines include a third data line configured to drive the third subpixel, and
the second color filter overlaps the third data line in the first area and overlaps the third color filter in the second area.

10. The display apparatus of claim 8, wherein the plurality of lines include a fourth data line configured to drive the fourth subpixel,
the fourth data line is disposed in the first area of the fourth subpixel, and
the third color filter overlaps the fourth data line in the first area and overlaps the second color filter in the second area.

11. The display apparatus of claim 8, wherein the plurality of lines include a pixel power line overlapped between the first subpixel and the fourth subpixel adjacent to the first subpixel, and
the first color filter overlaps the pixel power line in the first area and overlaps the color filter of the adjacent fourth subpixel and the pixel power line in the second area.

12. The display apparatus of claim 2, further comprising a light emitting element layer in the plurality of subpixels,
wherein the light emitting element layer includes:
a pixel electrode in the light emission area;
a light emitting layer on the pixel electrode and the non-light emission area; and
a reflective electrode on the light emitting layer,
wherein the reflective portion is a portion of the reflective electrode.

13. The display apparatus of claim 12, further comprising a color filter extending from the light emission area of the plurality of subpixels to at least a portion of the second area by passing through the first area,
wherein a distance L from an end of the color filter to an end of the light emission area is provided to satisfy:
L≥D*tan θ_{c},
where D is a distance from the light emitting layer and a lower surface of the color filter, and θ_{c} is a threshold angle at which light emitted from the light emitting layer is totally reflected on an upper surface of the substrate.

14. The display apparatus of claim 12, further comprising a color filter extending from the light emission area of the plurality of subpixels to at least a portion of the second area by passing through the first area,
wherein a distance L from an end of the color filter to an end of the light emission area is provided to satisfy:
L≥D*tan(arcsin(n1/n2)),
where D is a distance from the light emitting layer to a lower surface of the color filter, n1 is a refractive index of the light emitting layer, and n2 is a refractive index of the substrate.

15. The display apparatus of claim 13, wherein the plurality of subpixels include a white subpixel configured to emit white light, and a colored subpixel adjacent to the white subpixel, and
the color filter is a color filter of the colored subpixel adjacent to the white subpixel.

16. The display apparatus of claim 2, wherein the plurality of subpixels include a light extraction portion that overlaps the light emission area and includes a plurality of concave portions,
the light extraction portion is disposed to be adjacent to the pattern portion, and
the pattern portion includes an inclined surface formed in the first area and a bottom surface extended from the inclined surface and formed up to the second area.

17. The display apparatus of claim 16, wherein the inclined surface of the pattern portion forms an obtuse angle with the bottom surface.

18. The display apparatus of claim 1, wherein the pattern portion is spaced apart from the light emission area.

19. The display apparatus of claim 1, wherein the pattern portion has a width that decreases from the reflective portion toward the substrate.

20. The display apparatus of claim 16, wherein the plurality of subpixels include an overcoat layer on the substrate and a pixel electrode on the overcoat layer,
the overcoat layer includes a first layer including the plurality of concave portions, and a second layer between the first layer and the pixel electrode, and
the second layer extended to the first area and is in contact with a portion of the bottom surface of the pattern portion while covering the inclined surface of the pattern portion.

21. The display apparatus of claim 20, further comprising a bank covering an edge of the pixel electrode,
wherein the bank covers the second layer covering the inclined surface and is in contact with a portion of the bottom surface of the pattern portion.

22. The display apparatus of claim 21, wherein each of the second layer and the bank on the bottom surface of the pattern portion is discontinuous.

23. The display apparatus of claim 8, wherein the plurality of subpixels include a fifth subpixel adjacent to the first subpixel and configured to emit light of a same color as the first subpixel,
the fifth subpixel includes a first color filter,
the first subpixel includes a circuit area in the non-light emission area,
a gate line and a sensing line are disposed between the circuit area of the first subpixel and the fifth subpixel, and
the first color filter of the fifth subpixel overlaps the gate line and the sensing line and does not overlap the circuit area of the first subpixel.

24. A display apparatus comprising:
a substrate including a plurality of subpixels having a light emission area and a non-light emission area adjacent to the light emission area;
a pattern portion formed to be concave on the substrate, and surrounding the light emission area of the plurality of subpixels;
a reflective portion on the pattern portion; and
a plurality of lines configured to drive the plurality of subpixels,
wherein the non-light emission area includes a first area adjacent to the light emission area and a second area adjacent to the first area and spaced apart from the light emission area, and
a line, which is disposed in the first area, among the plurality of lines is a reflective line.

25. The display apparatus of claim 24, wherein each of the plurality of subpixels includes a bank disposed in the non-light emission area,
the first area is an area in which the banks of the respective subpixels are disposed, and
the second area is an area between the banks of the respective subpixels.

26. The display apparatus of claim 25, wherein the plurality of subpixels include a first subpixel and a second subpixel disposed to be adjacent to the first subpixel,
the first subpixel further includes a color filter disposed between the reflective line and the pattern portion, and
the color filter does not overlap the first area of the second subpixel.

27. The display apparatus of claim 26, wherein the first area of the second subpixel is an area between the light emission area of the second subpixel and the second area.

28. The display apparatus of claim 26, wherein the plurality of lines further include a line disposed in the second area, and the color filter partially overlaps the line disposed in the second area.

29. The display apparatus of claim 26, wherein the plurality of lines further include a line formed over the first area and the second area, and
a portion of the color filter overlaps the entire line in the second area.

30. The display apparatus of claim 25, further comprising a light emitting element layer in the plurality of subpixels,
wherein the light emitting element layer includes:
a pixel electrode in the light emission area;
a light emitting layer on the pixel electrode and the non-light emission area; and
a reflective electrode on the light emitting layer, and
the reflective portion is a portion of the reflective electrode.

31. The display apparatus of claim 30, further comprising a color filter extending from the light emission area to at least a portion of the second area by passing through the first area,
wherein a distance L from an end of the color filter to an end of the light emission area is provided to satisfy:
L≥D*tan(arcsin(n1/n2)),
where D is a distance from the light emitting layer to a lower surface of the color filter, n1 is a refractive index of the light emitting layer, and n2 is a refractive index of the substrate.

32. The display apparatus of claim 25, wherein the plurality of subpixels include a light extraction portion that overlaps the light emission area and includes a plurality of concave portions,
the light extraction portion is disposed to be adjacent to the pattern portion, and
the pattern portion includes an inclined surface formed in the first area and a bottom surface extended from the inclined surface and formed up to the second area.

33. The display apparatus of claim 32, wherein the plurality of subpixels include an overcoat layer on the substrate and a pixel electrode on the overcoat layer,
the overcoat layer includes a first layer including the plurality of concave portions, and a second layer between the first layer and the pixel electrode, and
the second layer extends to the first area and is in contact with a portion of the bottom surface of the pattern portion while covering the inclined surface of the pattern portion.

34. The display apparatus of claim 7, further comprising:
a first color filter provided in the first subpixel; and
a second color filter provided in the third subpixel,
wherein the second color filter includes an extended color filter extended from the third subpixel to the second subpixel and disposed to surround the second subpixel, and
the second color filter and the extended color filter are blue color filters.

35. The display apparatus of claim 34, wherein the extended color filter does not overlap the light emission area of the second subpixel.

36. The display apparatus of claim 34, wherein the extended color filter partially overlaps the first color filter in the non-light emission area between the first subpixel and the second subpixel.

37. The display apparatus of claim 34, wherein the plurality of lines include a first data line for driving the first subpixel and a second data line spaced apart from the first data line to drive the second subpixel,
the first data line is disposed in the first area,
the second data line is disposed in the second area,
the extended color filter partially overlaps the first data line, and
the extended color filter partially overlaps the second data line.

38. The display apparatus of claim 37, wherein the extended color filter includes a first color filter area disposed in the non-light emission area between the first subpixel and the second subpixel, and,
the first color filter area includes:
a first side sub-color filter area in which the extended color filter, the first data line and the first color filter overlap one another;
a second side sub-color filter area in which the extended color filter and the first color filter overlap each other; and
a third side sub-color filter area in which the extended color filter and the second data line overlap each other.

39. The display apparatus of claim 38, wherein light emitted through the second side sub-color filter area has a blackish color.

40. The display apparatus of claim 34, wherein the plurality of lines include a reference line disposed to be spaced apart from an upper side of the light emission area of the second subpixel,
the reference line is disposed in the first area, and
the extended color filter partially overlaps the reference line.

41. The display apparatus of claim 40, wherein the extended color filter includes a second color filter area disposed in the non-light emission area between the second subpixel and another second subpixel disposed to be adjacent to the second subpixel, and
the second color filter area includes:
a first upper sub-color filter area in which the extended color filter and the reference line overlap each other; and
a second upper sub-color filter area disposed to be adjacent to the first upper sub-color filter area.

42. The display apparatus of claim 41, wherein light emitted through the second upper sub-color filter area has a blueish color.

43. The display apparatus of claim 2, wherein the plurality of subpixels include:
a first subpixel emitting red light;
a second subpixel adjacent to the first subpixel and emitting white light;
a third subpixel adjacent to the second subpixel and emitting blue light; and
a fourth subpixel adjacent to the third subpixel and emitting green light,
the first subpixel includes a first color filter,
the third subpixel includes a second color filter,
the second color filter includes an extended color filter extended from the third subpixel to the second subpixel and disposed to surround the second subpixel, and
the second color filter and the extended color filter are blue color filters.

44. The display apparatus of claim 43, wherein the plurality of lines include a first data line for driving the first subpixel and a second data line spaced apart from the first data line to drive the second subpixel,
the first data line is disposed in the first area of the first subpixel,
the second data line is disposed in the first area of the second subpixel,
the extended color filter partially overlaps the first data line, and
the extended color filter partially overlaps the second data line.

45. The display apparatus of claim 44, wherein the extended color filter includes a first color filter area disposed in the non-light emission area between the first subpixel and the second subpixel, and
the first color filter area includes:
a first side sub-color filter area in which the extended color filter, the first data line and the first color filter overlap one another;
a second side sub-color filter area in which the extended color filter and the first color filter overlap each other; and
a third side sub-color filter area in which the extended color filter and the second data line overlap each other.

46. The display apparatus of claim 45, wherein light emitted through the second upper sub-color filter area has a blackish color.
